(19) United States
(12) Patent Application Publication
(10) Pub. No.: US 2015/0376447 A1
(43) Pub. Date: Dec. 31, 2015

(54) Curable resin composition containing aromatic polyester, and cured article thereof

(71) Applicant: NIPPON STEEL & SUMIKIN CHEMICAL CO., LTD., Tokyo (JP)

(72) Inventors: Masanao KAWABE, Fukuoka (JP); Niranjan Kumar SHRESTHA, Fukuoka (JP); Yuko HORITA, Chiba (JP)

(21) Appl. No.: 14/754,726

(22) Filed: Jun. 30, 2015

(30) Foreign Application Priority Data
Jun. 30, 2014 (JP) 2014-135021
Jun. 30, 2014 (JP) 2014-135082

(51) Int. Cl. C09D 167/04; C08G 63/06; H05K 1/03; B32B 15/09; B32B 15/092; C08K 7/18; C08K 5/00

(52) U.S. Cl. CPC C09D 167/04; C08K 7/18; C08G 63/065; C08K 5/0066; B32B 15/09; B32B 15/092; H05K 1/0353; B32B 2307/206; B32B 2457/08; B32B 2457/00; B32B 2307/7265

(57) ABSTRACT

Provided is a curable resin composition which: has high levels of dielectric characteristics required in an electrically insulating material application compatible with a high frequency; provides a cured article excellent in low water absorption rate and low linear expansion rate; and is excellent in wire embedding flatness and resin fluidity. Specifically, provided is an aromatic polyester obtained by condensing (a) an aromatic oxycarboxylic acid, (b) an aromatic polyvalent carboxylic acid or an aromatic polyhydric hydroxy compound, and (c) an aromatic monohydroxy compound or an aromatic monocarboxylic acid. Also provided is a curable resin composition containing the aromatic polyester (A), an epoxy resin (D) having two or more epoxy groups per molecule, and a curing accelerator (E).

### CROSS REFERENCE TO RELATED APPLICATIONS

This application claims the priority benefit of Japan application serial no. 2014-135021, filed on Jun. 30, 2014 and Japan application serial no. 2014-135082, filed on Jun. 30, 2014. The entirety of each of the above-mentioned patent applications is hereby incorporated by reference herein and made a part of this specification.

### BACKGROUND OF THE INVENTION

1. Field of the Invention

The present invention relates to a curable resin composition using an aromatic polyester, a curable composite material, cured articles thereof, a laminated body formed of the cured article of the curable composite material and a metal foil, a varnish for a circuit board material, a metal foil with a resin, an electrical and electronic part, and to a circuit board. The present invention also relates to an aromatic polyester which may be suitably used for the curable resin composition and a production method therefor.

2. Description of the Related Art

Along with an increase in amount of information communication in recent years, information communication in a high frequency band has started to be actively carried out. Accordingly, there is a demand for an electrically insulating material having more excellent electrical characteristics, in particular, a low dielectric constant and a low dielectric loss tangent for reducing a transmission loss in the high frequency band, especially small changes in dielectric characteristics after severe thermal history.

Meanwhile, along with pursuit of, for example, downsizing, multifunctionalization, and increased communication speed of an electronic device, there has been a demand for a further increase in density of a circuit board to be used for the electronic device. To meet such demand for the increase in density, an attempt has been made to allow the circuit board to have a multilayer structure. Such multilayer circuit board is formed by, for example: laminating an electrically insulating layer on an inner layer substrate formed of an electrically insulating layer and a conductor layer formed on a surface thereof; forming a conductor layer on the electrically insulating layer; and repeating the lamination of an electrically insulating layer and the formation of a conductor layer. A ceramic or a thermosetting resin is generally used as a material for forming the electrically insulating layer of such multilayer circuit board. Of those, an epoxy resin as the thermosetting resin is excellent in balance between economic efficiency and performance, and hence is widely used.

A general epoxy resin material for forming such electrically insulating layer is cured by, for example, being allowed to react with a curing agent having active hydrogen, such as a phenol compound, an amine compound, or a polyvalent carboxylic acid. In the curing, there has been a problem in that a ring-opening reaction of an epoxy group occurs owing to a reaction between the epoxy group and the active hydrogen to generate a hydroxy group having high polarity, which impairs hygroscopicity, a dielectric constant, a dielectric loss tangent, and the like. In addition, when an acid anhydride having no active hydrogen in the molecule is used as the curing agent, no hydroxy group is generated in the curing reaction with the epoxy resin except at an end at which the reaction is terminated. In actuality, however, the acid anhydride easily undergoes ring opening through moisture absorption to generate a carboxylic acid having active hydrogen, and hence generation of a hydroxy group cannot be completely avoided in the curing reaction. Thus, an insulating material having preferred electrical characteristics has not been obtained.

In addition, as an improved product based on the above-mentioned general epoxy resin material, in each of International Patent WO2010/87526A, Japanese Patent Application Laid-open No. 2002-12650, Japanese Patent Application Laid-open No. 2004-217869, and Japanese Patent Application Laid-open No. 2003-252957, there is disclosed a resin composition containing an epoxy resin, an active ester compound as a curing agent, and a curing accelerator.

However, it has been revealed that the following problems arise when an insulating resin layer of a printed board for an electronic material is formed using the resin composition disclosed in each of the above-mentioned patent literatures: the active ester compound as the curing agent is a non-crystalline compound, and hence a transmission loss in a high frequency band exceeding 10 GHz enlarges to lower reliability of a transmission signal; the resin layer has a high linear expansion rate, which leads to significant deformation of a laminated substrate, with the result that its thinning is difficult; and changes in characteristics at the time of water absorption are large, and hence reliability is insufficient.

Meanwhile, in Japanese Patent Application Laid-open No. Hei 5-93051, there is disclosed a resin composition for electronic part sealing containing, as a main component, a melt-processable polyester which is capable of forming an anisotropic melt phase and in which a functional group at a molecular chain end is blocked with a low-molecular compound having one or more aromatic rings and having a molecular weight of 350 or less. However, a melt-molding processing temperature range of the resin composition obtained by this technology is as high as 280° C. or more. Accordingly, in general, when a curable resin composition is obtained by blending the resin composition with an epoxy resin to be cured in a temperature range of from 150° C. to 200° C., there has been a problem in that a range of molding processing conditions is narrow and hence reliability is lowered in molding processing compatible with fine wiring. Further, there has also been a problem in that the melt-processable polyester has low solvent solubility and hence a varnish cannot be produced with a solvent generally used for a curable resin composition in which an epoxy-based resin is blended as a component. In Japanese Patent Application Laid-open No. Hei 5-93051, it is disclosed that: a silicone may be blended into a sealing material to decrease a strain, decrease a stress, and provide an adhesive property with an object to be sealed in a resin at the time of molding and curing, and at the time of use involving a rapid temperature change, and a silicone resin having an epoxy-modified alkyl group may be used; and various epoxy resins may each be used as a stabilizer. However, the melt-processable polyester is significantly restricted in terms of the processing temperature range and the solvent solubility as described above, and hence the epoxy-modified silicone resin and the various epoxy resins have not been used as main materials as curing resins in general thermosetting resin compositions, and have been limited to use as additives in thermoplastic resin compositions. Accordingly, there has been a problem in that the melt-processable polyester is not suitable for a production process of a printed wiring board in which an epoxy resin-based curable resin composition is generally used.

As described above, the epoxy resin material and the aromatic polyester, and the curable resin compositions thereof in the related art do not provide cured articles having dielectric characteristics required in an electrically insulating material application, in particular, an electrically insulating material application compatible with a high frequency exceeding 10 GHz, and are insufficient also in terms of low water absorbing property, resin fluidity, linear expansion coefficient, and wire embedding flatness.

### CITATION LIST

### Patent Literature

Patent Literature 1: WO2010/87526A1
Patent Literature 2: JP2002-12650A
Patent Literature 3: JP2004-217869A
Patent Literature 4: JP2003-252957A
Patent Literature 5: JP05-93051A

### SUMMARY OF THE INVENTION

In view of the problems of the related art described above, the present invention provides a material which is excellent in low water absorbing property, resin fluidity, linear expansion coefficient, and wire embedding flatness, and has dielectric characteristics required in an electrically insulating material application compatible with a high frequency exceeding 10 GHz, the characteristics being unable to be achieved by the epoxy resin material and the aromatic polyester material of the related art.

The inventors of the present invention have found that a curable resin composition containing a specific aromatic polyester is effective for solving the above-mentioned problems. Thus, the inventors have completed the present invention.

That is, according to one embodiment of the present invention, there is provided a curable resin composition, including:

an aromatic polyester as a component (A); and

an epoxy resin having two or more epoxy groups per molecule as a component (D),

in which the component (A) is an aromatic polyester obtained by condensing:
(a) an aromatic oxycarboxylic acid;
(b) an aromatic polyvalent carboxylic acid or an aromatic polyhydric hydroxy compound; and
(c) an aromatic monohydroxy compound or an aromatic monocarboxylic acid.

The aromatic oxycarboxylic acid (a) is preferably at least one kind of compound selected from the following group (4).

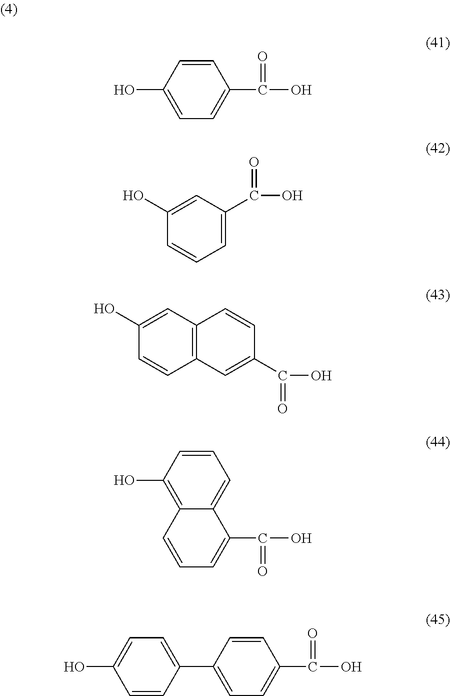 [SMILES: O=C(O)c1ccc(O)cc1 ; O=C(O)c1cccc(O)c1 ; O=C(O)c1ccc2cc(O)ccc2c1 ; O=C(O)c1cccc2c(O)cccc12 ; O=C(O)c1ccc(-c2ccc(O)cc2)cc1]

The aromatic polyvalent carboxylic acid or the aromatic polyhydric hydroxy compound (b) is preferably at least one kind of compound selected from the following group (5) or the following group (6).

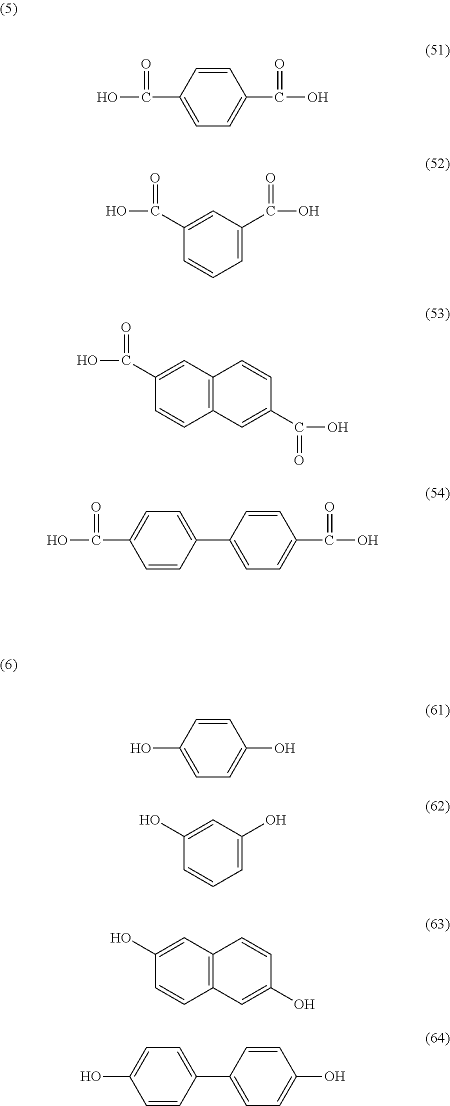

The aromatic monohydroxy compound or the aromatic monocarboxylic acid (c) is preferably at least one kind of compound selected from the following group (7) or following group (8).

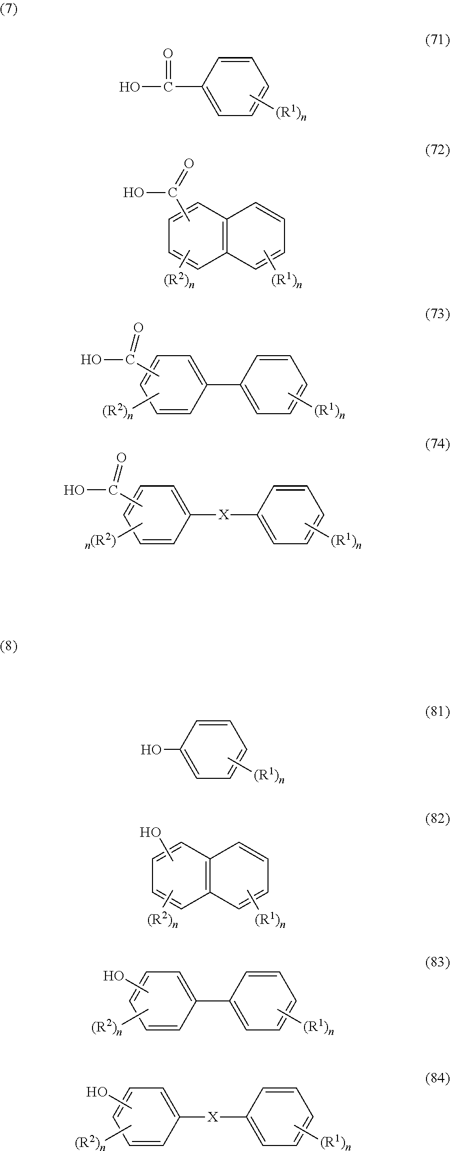

(In the formulae, R¹ and R² each independently represent an alkyl group having 1 to 10 carbon atoms, an alkoxy group having 1 to 10 carbon atoms, a phenyl group, or a benzyl group, X in the formula (74) and the formula (84) represents an alkylene having 1 to 4 carbon atoms, or —O—, and n represents an integer of from 0 to 2.)

The curable resin composition of the present invention is preferably such that the component (A) has an aromatic oxycarboxylic acid unit (a′), an aromatic polyvalent carboxylic acid or aromatic polyhydric hydroxy compound unit (b′), and an aromatic monohydroxy compound or aromatic monocarboxylic acid unit (c′), which form the aromatic polyester, and with respect to the total of the units, a mole fraction of an aromatic compound residue having two or more rings in each of the units is 0.25 or more.

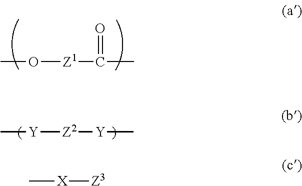

(In the formulae, Z¹ and Z² each independently represent a divalent aromatic group, Z³ represents a monovalent aromatic group, and X and Y each represent an ether group or a ketone group.)

The curable resin composition of the present invention is preferably such that the component (D) is an epoxy resin having an area percentage of aromatic carbon atoms in a resonance line area of all carbon atoms detected in ¹³C-NMR of from 30% to 95%. In addition, the content of the component (D) is preferably from 0.1 mol to 1.5 mol with respect to 1 mol of an ester bond in the aromatic polyester.

In the curable resin composition of the present invention, with respect to the total of the aromatic oxycarboxylic acid unit (a′), the aromatic polyvalent carboxylic acid or aromatic polyhydric hydroxy compound unit (b′), and the aromatic monohydroxy compound or aromatic monocarboxylic acid unit (c′), which form the aromatic polyester as the component (A), it is appropriate that the mole fraction of an aromatic compound residue having two or more rings in each of the units is 0.25 or more. In addition, with respect to the total of the aromatic oxycarboxylic acid unit (a′), the aromatic polyvalent carboxylic acid or aromatic polyhydric hydroxy compound unit (b′), and the aromatic monohydroxy compound or aromatic monocarboxylic acid unit (c′), it is appropriate that the mole fractions of the respective units satisfy (a′)=0.15 to 0.94, (b′)=0.01 to 0.35, and (c′)=0.05 to 0.60.

An example of (a) the aromatic oxycarboxylic acid is at least one kind of compound selected from the group (4).

(b) The aromatic polyvalent carboxylic acid or the aromatic polyhydric hydroxy compound is (b1) an aromatic polyvalent carboxylic acid in some cases, and is (b2) an aromatic polyhydric hydroxy compound in other cases. Similarly, (c) the aromatic monohydroxy compound or the aromatic monocarboxylic acid is (c1) an aromatic monohydroxy compound in some cases, and is (c2) an aromatic monocarboxylic acid in other cases. When (b1) the aromatic polyvalent carboxylic acid is used, (c1) the aromatic monohydroxy compound is used, and when (b2) the aromatic polyhydric hydroxy compound is used, (c2) the aromatic monocarboxylic acid is used.

In the case of using (b1) the aromatic polyvalent carboxylic acid and (c1) the aromatic monohydroxy compound, an example of (b1) the aromatic polyvalent carboxylic acid is an aromatic polyvalent carboxylic acid selected from the group (5), and an example of (c1) the aromatic monohydroxy compound is a compound selected from the group (8).

In the case of using (b2) the aromatic polyhydric hydroxy compound, when (c2) the aromatic monocarboxylic acid is used, an example of (b2) the aromatic polyhydric hydroxy compound is a compound selected from the group (6), and an example of (c2) the aromatic monocarboxylic acid is a compound selected from the group (7).

One or more kinds of components selected from components (E) to (H) are desirably further blended into the curable resin composition of the present invention. Here, the component (E) is a curing accelerator, the component (F) is a high-molecular-weight resin having a weight-average molecular weight (Mw) of 10,000 or more, the component (G) is an inorganic filler, and the component (H) is a flame retardant. In addition, examples of the high-molecular-weight resin as the component (F) include a polysulfone resin, a polyether sulfone resin, a polyphenylene ether resin, a phenoxy resin, a polycycloolefin resin, a hydrogenated styrene-butadiene copolymer, a hydrogenated styrene-isoprene copolymer, a polyimide resin, a polyamide imide resin, a polyether imide resin, a polycarbonate resin, a polyether ether ketone resin, and a polyester resin (except the aromatic polyester as the component (A)).

According to another embodiment of the present invention, there are provided a varnish for a circuit board material, which is obtained by dissolving the curable resin composition in a solvent, a cured article, which is obtained by curing the curable resin composition, an electrical and electronic part, which is obtained by using the cured article, and a circuit board, which is obtained by using the cured article.

According to another embodiment of the present invention, there are provided a curable composite material, including: the curable resin composition; and a base material, a composite material cured article, which is obtained by curing the curable composite material, and a laminated body, including: a layer of the composite material cured article; and a metal foil layer.

According to another embodiment of the present invention, there is provided an aromatic polyester, including:

the following repeating structural units (a′) and (b′); and

the following end structural unit (c′),

in which:

a mole fraction of the structural unit (a′) is from 15% to 94%, a mole fraction of the structural unit (b′) is from 1% to 35%, and a mole fraction of the structural unit (c′) is from 5% to 60%;

the sum of a hydroxy group equivalent and a carboxyl group equivalent is 1,000 (g/eq) or more; and

a catalyst-derived impurity amount is 1.0 wt % or less.

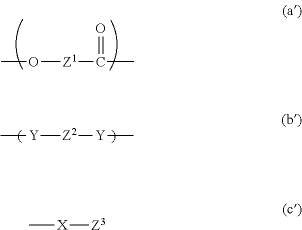

(In the formulae, Z¹ and Z² each independently represent a divalent aromatic group, Z³ represents a monovalent aromatic group, and X and Y each represent an ether group or a ketone group.)

It should be noted that it is preferred that X represent a ketone group when Y represents an ether group, and represent an ether group when Y represents a ketone group.

In the aromatic polyester, it is preferred that the Z¹ represent at least one kind of group selected from the following group (1), the Z² represent at least one kind of group selected from the following group (2), and the Z³ represent at least one kind of group selected from the following group (3).

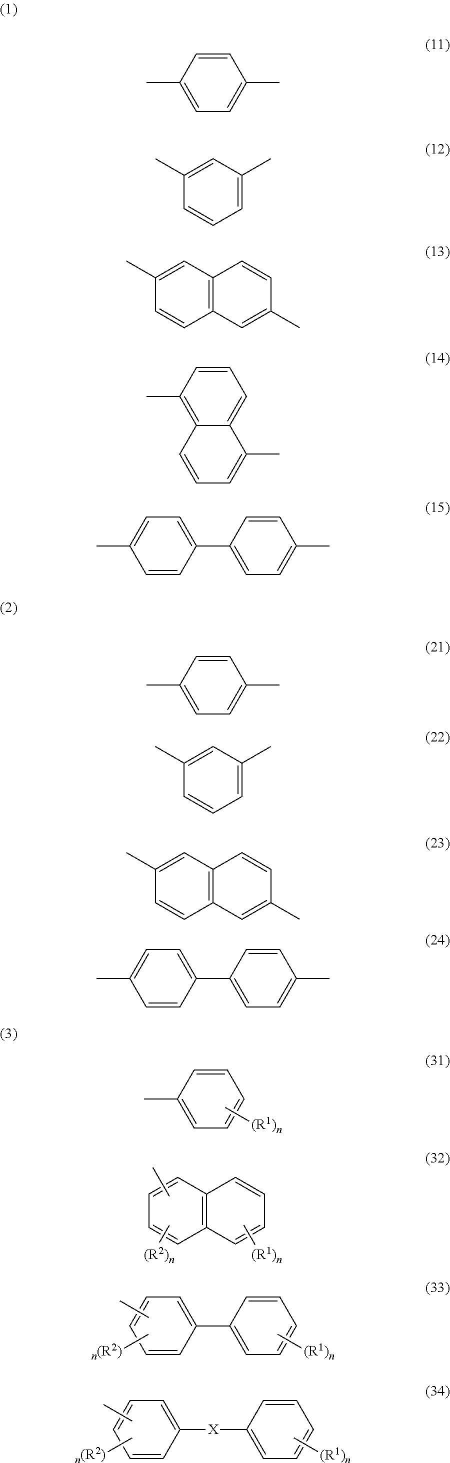

(In the formulae, R¹ and R² each independently represent an alkyl group having 1 to 10 carbon atoms, an alkoxy group having 1 to 10 carbon atoms, a phenyl group, or a benzyl group, X in the formula (34) represents an alkylene having 1 to 4 carbon atoms, or —O—, and n represents an integer of from 0 to 2.)

In the aromatic polyester, it is preferred that the repeating structural unit (b′) be an aromatic polyvalent carboxylic acid residue or an aromatic polyhydric hydroxy compound residue, and the end structural unit (c′) be an aromatic monohydroxy compound residue or an aromatic monocarboxylic acid residue.

According to another embodiment of the present invention, there is provided a production method for an aromatic polyester, including:

blending an aromatic oxycarboxylic acid (a), an aromatic polyvalent carboxylic acid or an aromatic polyhydric hydroxy compound (b), and an aromatic monohydroxy compound or an aromatic monocarboxylic acid (c) so that a mole fraction of the aromatic oxycarboxylic acid (a) is from 15% to 94%, a mole fraction of the aromatic polyvalent carboxylic acid or the aromatic polyhydric hydroxy compound (b) is from 1% to 35%, and a mole fraction of the aromatic monohydroxy compound or the aromatic monocarboxylic acid (c) is from 5% to 60%; and

condensing the component (a), the component (b), and the component (c) in the presence of an esterification catalyst.

In the production method for an aromatic polyester, it is preferred that the aromatic oxycarboxylic acid (a) be at least one kind of compound selected from the group (4), the aromatic polyvalent carboxylic acid or the aromatic polyhydric hydroxy compound (b) be at least one kind of compound selected from the group (5) or the group (6), and the aromatic monohydroxy compound or the aromatic monocarboxylic acid (c) be at least one kind of compound selected from the group (7) or the group (8).

The curable resin composition containing an aromatic polyester or the cured article obtained by curing the curable resin composition of the present invention has high levels of dielectric characteristics, and has a low water absorption rate even after hygrothermal history under severe conditions. In addition, the curable resin composition or the cured article is excellent in resin fluidity, has a low linear expansion rate, and is excellent in wire embedding flatness. Further, the cured article is excellent in chemical resistance, low water absorbing property, heat resistance, flame retardancy, and mechanical characteristics. Besides, the cured article is free of a molding failure phenomenon, such as warping, and is excellent in electrical reliability because of excellent adhesiveness with a dissimilar material.

By virtue of having such excellent characteristics, the curable resin composition or the cured article may be suitably used as an electrically insulating material compatible with a high frequency exceeding 10 GHz. Therefore, the curable resin composition or the cured article is suitably used as a dielectric material, an insulating material, or a heat-resistant material in an advanced material field, such as an electrical industry or a space and aircraft industry, and may be used, for example, in a material for an electrical and electronic part, in particular, as a circuit board material for a single-sided, double-sided, or multilayer printed board, a flexible printed board, a build-up substrate, or the like.

### DETAILED DESCRIPTION OF THE PREFERRED EMBODIMENTS

Now, the present invention is further described.

An aromatic polyester to be incorporated into a curable resin composition of the present invention is obtained by condensing (a) an aromatic oxycarboxylic acid, (b) an aromatic polyvalent carboxylic acid or an aromatic polyhydric hydroxy compound, and (c) an aromatic monohydroxy compound or an aromatic monocarboxylic acid. The aromatic polyester produced by condensing the above-mentioned monomers has structural units (a′), (b′), and (c′) derived from (a) the aromatic oxycarboxylic acid, (b) the aromatic polyvalent carboxylic acid or the aromatic polyhydric hydroxy compound, and (c) the aromatic monohydroxy compound or the aromatic monocarboxylic acid. Hereinafter, (a) the aromatic oxycarboxylic acid, (b) the aromatic polyvalent carboxylic acid or the aromatic polyhydric hydroxy compound, and (c) the aromatic monohydroxy compound or the aromatic monocarboxylic acid are sometimes referred to as “component (a)”, “component (b)”, and “component (c)”, respectively, and the structural unit derived from (a) the aromatic oxycarboxylic acid, the structural unit derived from the component (b), and the structural unit derived from the component (c) are sometimes referred to as “structural unit (a′)”, “structural unit (b′)”, and “structural unit (c′)”, respectively.

(b) The aromatic polyvalent carboxylic acid or the aromatic polyhydric hydroxy compound is (b1) an aromatic polyvalent carboxylic acid in some cases, and is (b2) an aromatic polyhydric hydroxy compound in other cases. It is preferred to use any one of the (b1) and the (b2). When both the (b1) and the (b2) are used, it is appropriate that any one of the compounds be used in a larger amount so that a COOH group or a OH group may be present in an excess amount.

Similarly, (c) the aromatic monohydroxy compound or the aromatic monocarboxylic acid is (01) an aromatic monohydroxy compound in some cases, and is (c2) an aromatic monocarboxylic acid in other cases. When the (b1) is used, the (c1) is used, and when the (b2) is used, the (c2) is used, to allow the molar ratio of the COOH group to the OH group to approach 1.0. When both the (b1) and the (b2) are used, any one of the compounds is used in a larger amount and the (c1) or the (c2) is used in an amount corresponding to the excess COOH group or OH group.

In the same manner as above, those components and structural units derived therefrom are sometimes referred to as “component (b1)”, “component (b2)”, “component (c1)”, “component (c2)”, “structural unit (b1′)”, “structural unit (b2′)”, “structural unit (c1′)”, and “structural unit (c2′)”, respectively.

The combination of the component (b) and the component (c) allows a molecular chain end of the aromatic polyester to be capped with an aryloxycarbonyl group or an arylcarbonyloxy group. Accordingly, even when the molecular end reacts with an epoxy group, a hydroxy group having high polarity is not generated, and hence a cured article to be obtained has such a structural feature that the amount of polar groups is small. Therefore, its dielectric characteristics and low water absorption rate property are excellent. From the viewpoint of a balance between the above-mentioned characteristics and productivity, it is preferred that the aromatic polyester have a sum of a hydroxy group equivalent (OH equivalent) and a carboxyl group equivalent (COOH equivalent) of 1,000 or more, preferably from 2,000 to 30,000, more preferably from 3,000 to 20,000. It is more preferred that the hydroxy group equivalent and the carboxyl group equivalent of the aromatic polyester be each 1,000 or more. Herein, the unit of each of the hydroxy group equivalent and the carboxyl group equivalent of the aromatic polyester is g/eq, which represents the number of grams of the aromatic polyester per 1 equivalent. When the hydroxy group equivalent of the aromatic polyester is represented by X and its carboxyl group equivalent is represented by Y, the sum is X+Y.

In order to adjust the sum of the hydroxy group equivalent and the carboxyl group equivalent to 1,000 or more, it is necessary to control the introduction ratio of the aryloxycarbonyl group or the arylcarbonyloxy group into the molecular chain end of the aromatic polyester. In other words, the COOH group or the OH group present at the end is capped as completely as possible with the component (c). To that end, the component (c) is used in an amount corresponding to the COOH group or the OH group at the end. In general, in order to efficiently introduce a functional group into the end through a polycondensation reaction, an excess of a monofunctional compound for introducing an end functional group is added to generate an end group at the final stage of the reaction. In this case, a step of removing an unreacted monofunctional compound after the completion of the reaction is needed, resulting in difficulty in industrial implementation, specifically an increase in cost due to an increase in number of steps. Meanwhile, when the addition amount of the monofunctional compound for introducing an end functional group is decreased, in the case of melt polycondensation, when conditions at the final stage of the reaction are severe, the monofunctional compound is evaporated out of the system and the molecular weight is increased to become difficult to control to a target molecular weight. On the other hand, it is not preferred to render the conditions at the final stage of the reaction milder because it becomes difficult to sufficiently evaporate acetic anhydride to be used for accelerating the condensation reaction, acetic acid to be generated as a by-product, and the like, resulting in the degradation of dielectric characteristics. It should be noted that, of course, monomers including the component (a), the component (b), and the component (c) are used so that carboxy groups and hydroxy groups therein are equivalent, and the condensation reaction is caused to sufficiently proceed so as to prevent unreacted carboxy groups and hydroxy groups from remaining to the extent possible.

In the aromatic polyester to be incorporated into the curable resin composition of the present invention, the total amount of impurities derived from a catalyst to be used for esterification (esterification catalyst), for example, acetic acid and acetic anhydride derived from the catalyst when the catalyst is acetic anhydride, is preferably 1.0 wt % or less. The total amount is preferably 0.5 wt % or less, and is more preferably from 0.0001 wt % to 0.2 wt % from the viewpoint of a balance with productivity. With this, the amount of a polar impurity in the curable resin composition is reduced, and its dielectric characteristics and low water absorption rate property become excellent.

In order to adjust the total amount to 1.0 wt % or less, it is necessary to control a degree of vacuum and a temperature at the final stage of the reaction in the production of the aromatic polyester by melt polycondensation. However, when the conditions at the final stage of the reaction are severe, the monofunctional compound for introducing an end functional group is evaporated out of the system and the molecular weight is increased to become difficult to control to a target molecular weight. Accordingly, it is not desired to excessively increase the degree of vacuum and the temperature.

In addition, in the curable resin composition of the present invention, with respect to the total of the structural units (a′), (b′), and (c′) forming the aromatic polyester, it is preferred to set the mole fraction of a structural unit having an aromatic compound residue having two or more rings in these structural units to 0.25 or more, preferably 0.30 or more. When the mole fraction is set to fall within such range, the dielectric characteristics and the low water absorbing property become excellent. In addition, also with respect to all structural units of the aromatic polyester, it is preferred to set the mole fraction of the structural unit having an aromatic compound residue having two or more rings to 0.25 or more, preferably 0.30 or more. It should be noted that a compound which provides the structural unit having an aromatic compound residue having two or more rings is exemplified by compounds represented by the formulae (43) to (45) of the group (4), the formulae (53) to (54) of the group (5), the formulae (82) to (84) of the group (8), the formulae (63) to (64) of the group (6), and the formulae (72) to (74) of the group (7).

The use ratios of the component (a), the component (b), and the component (c) corresponds to the presence ratios (mole fractions) of the structural units (a′), (b′), and (c′) when the whole amounts thereof react. The respective mole fractions of the structural units (a′), (b′), and (c′) with respect to the total of the structural units (a′), (b′), and (c′) preferably satisfy (a′)=0.15 to 0.94, (b′)=0.01 to 0.35, and (c′)=0.05 to 0.60, more preferably (a′)=0.15 to 0.75, (b′)=0.5 to 0.30, and (c′)=0.10 to 0.55.

When the mole fraction of the structural unit (a′) is less than 0.15, the molding processing temperature of the aromatic polyester tends to increase, and when the mole fraction of the structural unit (a′) is more than 0.94, solvent solubility tends to decrease. When the mole fraction of the structural unit (b′) is less than 0.01, the dielectric characteristics tend to lower, and when the mole fraction of the structural unit (b′) is more than 0.35, fluidity tends to lower. When the mole fraction of the structural unit (c′) is less than 0.05, the fluidity of the resin tends to lower, and when the mole fraction of the structural unit (c′) is more than 0.60, the dielectric characteristics tend to lower.

In addition, from the viewpoint of the control of the molecular weight of the aromatic polyester, when the component (b) is (b1) the aromatic polyvalent carboxylic acid, the component (c) is preferably (c1) the aromatic monohydroxy compound (this combination is hereinafter referred to as “composition A), and when the component (b) is (b2) the aromatic polyhydric hydroxy compound, the component (c) is preferably (c2) the aromatic monocarboxylic acid (this combination is hereinafter referred to as “composition B”).

In the composition A and the composition B, from the viewpoints of the dielectric characteristics and heat resistance, the component (a) is preferably at least one kind of compound selected from the group (4), more preferably a compound represented by the formula (41), (43), or (45), most preferably a compound represented by the formula (41) or (43).

In the composition A, the component (b) is the component (b1) and the component (c) is the component (c1). In addition, from the viewpoints of the dielectric characteristics and the heat resistance, the component (b1) is preferably at least one kind of compound selected from the group (5), more preferably a compound represented by any one of the formulae (51) to (53), most preferably a compound represented by the formula (51) or (52).

From the viewpoints of the dielectric characteristics and the heat resistance, the component (c1) is preferably at least one kind of compound selected from the group (8), more preferably a compound represented by any one of the formulae (81) to (83), most preferably a compound represented by the formula (82) or (83). In the formulae, R¹ and R² each independently represent an alkyl group having 1 to 10 carbon atoms, an alkoxy group having 1 to 10 carbon atoms, a phenyl group, or a benzyl group. Of those, an alkoxy group or a phenyl group is preferred from the viewpoints of thermal stability and solubility. X in the formula (84) represents an alkylene having 1 to 4 carbon atoms, or —O—. Of those, —O— is preferred from the viewpoints of the thermal stability and the solubility. n represents an integer of from 0 to 2.

In the composition B, the component (b) is the component (b2) and the component (c) is the component (c2). In addition, from the viewpoints of the dielectric characteristics and the heat resistance, the component (b2) is preferably at least one kind of compound selected from the group (6), more preferably a compound represented by the formula (61), (62), or (64).

From the viewpoints of the dielectric characteristics and the heat resistance, at least one kind of compound selected from the group (7) is preferably used as the component (c1), and the component is more preferably a compound represented by any one of the formulae (71) to (73), most preferably a compound represented by the formula (71) or (72). In the formulae (71) to (74), R¹ and R² each independently represent an alkyl group having 1 to 10 carbon atoms, an alkoxy group having 1 to 10 carbon atoms, a phenyl group, or a benzyl group. Of those, an alkoxy group or a phenyl group is preferred from the viewpoints of thermal stability and solubility. X in the formula (74) represents an alkylene having 1 to 4 carbon atoms, or —O—. Of those, —O— is preferred from the viewpoints of the thermal stability and the solubility. n represents an integer of from 0 to 2.

The aromatic polyester to be incorporated into the curable resin composition of the present invention has a structure in which a molecular end is capped with the component (c). Accordingly, when the aromatic polyester is prepared into a curable resin composition with an epoxy resin and the curable resin composition is cured to provide a cured article, the generation of a hydroxy group is suppressed and satisfactory dielectric characteristics are obtained. The molecular end on each of both sides is preferably capped, but it is acceptable to cap the end on only one side. Out of all molecular ends of the aromatic polyester, preferably 25% or more, more preferably 50% or more, most preferably 75% or more are capped.

In addition, the aromatic polyester to be incorporated into the curable resin composition of the present invention is preferably a liquid-crystalline polymer which forms an anisotropic melt phase showing optical anisotropy at the time of melting. When the aromatic polyester shows liquid crystallinity, polymer molecules are highly aggregated to suppress the movement of polar molecules due to an external electric field, and thus the dielectric characteristics are further improved. Such liquid-crystalline polymer is generally classified as a thermotropic liquid crystal polymer.

The thermotropic liquid crystal polymer has a property by which polymer molecules are in regular parallel alignment in a molten state. Such state is often called a liquid crystal state or a nematic phase of a liquid-crystalline substance. In general, the structure of such thermotropic liquid crystal polymer is elongated, is flat, has significantly high rigidity along the long axis of the molecule, and has multiple chain extension bonds in a coaxial or parallel relationship. The formation of an anisotropic melt phase may be confirmed by a common polarization inspection method utilizing crossed polarizers. Specifically, a Leitz polarizing microscope is used to observe a molten sample mounted on a Leitz hot stage under a nitrogen atmosphere at a magnification of 40. When the molten sample has optical anisotropy, the molten sample transmits light when inspected between the crossed polarizers. Even when the molten sample is in a state of rest, polarized light is transmitted.

In addition, the aromatic polyester to be incorporated into the curable resin composition of the present invention may contain another polyester backbone or polyesteramide backbone which itself does not show anisotropy at the time of melting (hereinafter collectively referred to as “other backbone”) in the same molecular chain as long as optical anisotropy at the time of melting is not impaired. The other backbone is desirably a polyalkylene terephthalate backbone whose alkylene has 4 or less carbon atoms, more suitably a polyethylene terephthalate backbone or a polybutylene terephthalate backbone.

In the case of the composition A, the aromatic polyester to be incorporated into the curable resin composition of the present invention is obtained by, for example, subjecting the aromatic oxycarboxylic acid and the aromatic polyvalent carboxylic acid to polycondensation to synthesize a polyester having carboxy groups at both ends, and esterifying the carboxy groups with the aromatic monohydroxy compound (dehydration esterification reaction). In addition, the aromatic polyester may be produced by a transesterification reaction or a direct polycondensation reaction as well as the dehydration esterification reaction. For example, in the transesterification reaction, the aromatic polyester is obtained by acetylating the aromatic oxycarboxylic acid and the aromatic monohydroxy compound with acetic anhydride, followed by acidolysis with the aromatic polyvalent carboxylic acid. In the case of melt polycondensation utilizing the transesterification reaction, the respective monomer units of the aromatic polyester are rearranged through the transesterification reaction, and hence even when the aromatic monohydroxy compound is added from the initial stage of the polycondensation, an aromatic polyester having the aromatic monohydroxy compound introduced at an end can be efficiently synthesized.

When the direct polycondensation reaction is utilized, the aromatic polyester is obtained by subjecting the aromatic oxycarboxylic acid compound, the aromatic polyvalent carboxylic acid compound, and the aromatic monohydroxy compound to dehydration polycondensation under the coexistence of a catalyst.

The reaction efficiency of the dehydration esterification reaction is generally low, and hence it is preferred to perform the transesterification reaction through acetylation with acetic anhydride, or to utilize the direct polycondensation reaction.

In addition, in the case of the composition B, the aromatic polyester is obtained by, for example, subjecting the aromatic oxycarboxylic acid and the aromatic polyhydric hydroxy compound to polycondensation to synthesize a polyester having hydroxy groups at both ends, and esterifying the hydroxy groups with the aromatic monocarboxylic acid (dehydration esterification reaction). In addition, the aromatic polyester may be produced by a transesterification reaction or a direct polycondensation reaction as well as the dehydration esterification reaction. The aromatic polyester is obtained by acetylating the aromatic oxycarboxylic acid and the aromatic polyhydric hydroxy compound with acetic anhydride, followed by acidolysis with the aromatic monocarboxylic acid. As described above, in the case of melt polycondensation utilizing the transesterification reaction, the respective monomer units of the aromatic polyester are rearranged through the transesterification reaction, and hence even when the aromatic monocarboxylic acid is added from the initial stage of the polycondensation, an aromatic polyester having the aromatic monocarboxylic acid introduced at an end can be efficiently synthesized.

When the direct polycondensation reaction is utilized, the aromatic polyester is obtained by subjecting the aromatic oxycarboxylic acid compound, the aromatic polyhydric hydroxy compound, and the aromatic monocarboxylic acid to dehydration polycondensation under the coexistence of a catalyst.

The reaction efficiency of the dehydration esterification reaction is generally low, and hence it is preferred to perform the transesterification reaction through acetylation with acetic anhydride, or to utilize the direct polycondensation reaction.

The molecular weight of the aromatic polyester to be incorporated into the curable resin composition of the present invention and the number of moles of an ester bond in its molecule are not particularly limited, and may be arbitrarily set by adjusting a molar ratio among the component (a), the component (b), and the component (c). From the viewpoint of achieving both heat resistance improvement and solubility in an organic solvent, it is preferred that the molecular weight (Mn) be from 300 to 10,000 and the number of moles of the ester bond in the molecule be from 2 to 30. The molecular weight is more preferably from 500 to 5,000, and the molecular weight is most preferably from 500 to 2,000. It should be noted that the molecular weight and a molecular weight distribution may be measured by measuring a molecular weight in terms of polystyrene (PS) through the use of GPC (HLC-8120GPC manufactured by Tosoh Corporation) and a calibration curve prepared with monodispersed PS. In addition, the aromatic polyester contains the structural units (a′), (b′), and (c′) as main components. The structural units (a′), (b′), and (c′) preferably account for 50 mol % or more, more preferably 80 mol % or more of all structural units. When the structural units (a′), (b′), and (c′) are the main components, the dielectric characteristics and the low water absorbing property tend to be satisfactory.

When impurities, such as an unreacted raw material, and an organic compound and an inorganic compound each containing a halogen or an alkali metal as a by-product, remain in the aromatic polyester to be incorporated into the curable resin composition of the present invention, the impurities may contribute to impairing the low hygroscopicity, the low dielectric constant, and the low dielectric loss tangent of an epoxy resin cured article to be obtained by curing the epoxy resin composition. Accordingly, it is preferred to reduce the remaining amount of the impurities (impurity amount) to the extent possible, and in particular, it is preferred to control the total amount of acetic acid to 1.0 wt % or less, or 100 ppm or less if possible. The impurity amount is determined by a known analysis method, such as gas chromatographic analysis, fluorescent X-ray analysis, or neutralization titration analysis. In addition, as a method of reducing the impurity amount, there may be used a known washing method, such as: a washing method using alkaline water containing a hydroxide or a carbonate of an alkali metal, an alkaline-earth metal, or the like; a washing method using acidic water containing hydrochloric acid, a phosphate, or the like; a deionized water washing method; a recrystallization method; or a reprecipitation method.

Next, the curable resin composition of the present invention contains, as an essential component, an epoxy resin having two or more epoxy groups per molecule as a component (D) in addition to the aromatic polyester as the component (A).

Now, the epoxy resin as the component (D) to be blended into the curable resin composition of the present invention is described.

The component (D) is an epoxy resin having two or more epoxy groups per molecule. It is preferred to use one or more kinds selected from the group consisting of: an epoxy resin (D1) having two or more epoxy groups per molecule and having an aromatic structure; an epoxy resin (D2) having two or more epoxy groups per molecule and having a cyanurate structure; and an epoxy resin (D3) having two or more epoxy groups per molecule and having an alicyclic structure. The D3 desirably has an alicyclic structure having 3 to 8 carbon atoms.

In addition, the component (D) preferably has a percentage of the resonance line of aromatic carbon atoms in the resonance line area of all carbon atoms detected in ¹³C-NMR of from 30% to 95%. When the percentage falls within such range, an excellent balance between the dielectric characteristics and flame retardancy is obtained. The percentage is more preferably from 35% to 85%. The percentage corresponds to the ratio of the constituent carbon atoms of an aromatic ring in all constituent carbon atoms of the epoxy resin. From such viewpoint, it can be said that it is desired to use the epoxy resin (D1) or (D2) having an aromatic structure, or to use the epoxy resin (D1) or (D2) in combination with another epoxy resin.

Additionally preferred examples thereof may include a bisphenol A-type epoxy resin, a bisphenol F-type epoxy resin, a bisphenol S-type epoxy resin, an alkylphenol novolac-type epoxy resin, a xylylene-modified phenol novolac-type epoxy resin, a xylylene-modified alkylphenol novolac-type epoxy resin, a biphenyl-type epoxy resin, a dicyclopentadiene-type epoxy resin, an epoxylated product of a condensate of a phenol and an aromatic aldehyde having a phenolic hydroxyl group, and a naphthalene-type epoxy resin. Each of those epoxy resins may be used alone, or two or more kinds thereof may be used in combination.

Preferred examples of the bisphenol F-type epoxy resin include an epoxy resin containing as a main component a diglycidyl ether of 4,4′-methylenebis(2,6-dimethylphenol), an epoxy resin containing as a main component a diglycidyl ether of 4,4′-methylenebis(2,3,6-trimethylphenol), and an epoxy resin containing as a main component a diglycidyl ether of 4,4′-methylenebisphenol. Of those, an epoxy resin containing as a main component a diglycidyl ether of 4,4′-methylenebis(2,6-dimethylphenol) is preferred. The bisphenol F-type epoxy resin is available as a commercial product under the trade name “YSLV-80XY” from Nippon Steel & Sumikin Chemical Co., Ltd.

Preferred examples of the biphenyl-type epoxy resin include epoxy resins such as 4,4′-diglycidylbiphenyl and 4,4′-diglycidyl-3,3′,5,5′-tetramethylbiphenyl. The biphenyl-type epoxy resin is available as a commercial product under the trade name “YX-4000” or “YL-6121H” from Mitsubishi Chemical Corporation.

A preferred example of the dicyclopentadiene-type epoxy resin is a phenol novolac epoxy monomer having a dicyclopentadiene skeleton.

Preferred examples of the naphthalene-type epoxy resin include 1,2-diglycidylnaphthalene, 1,5-diglycidylnaphthalene, 1,6-diglycidylnaphthalene, 1,7-diglycidylnaphthalene, 2,7-diglycidylnaphthalene, triglycidylnaphthalene, 1,2,5,6-tetraglycidylnaphthalene, and modified naphthalene-type epoxy resins such as a naphthol-aralkyl-type epoxy resin, a naphthalene skeleton-modified cresol novolac-type epoxy resin, a methoxynaphthalene-modified cresol novolac-type epoxy resin, a naphthylene ether-type epoxy resin, and a methoxynaphthalene dimethylene-type epoxy resin.

Of those epoxy resins, a bisphenol F-type epoxy resin, an alkylphenol novolac-type epoxy resin, a xylylene-modified phenol novolac-type epoxy resin, a xylylene-modified alkylphenol novolac-type epoxy resin, a biphenyl-type epoxy resin, a dicyclopentadiene-type epoxy resin, or a naphthalene-type epoxy resin is more suitably used from the viewpoints of compatibility with the aromatic polyester as the component (A), dielectric characteristics, and small warping of a molded article.

The Mw of the epoxy resin as the component (D) is preferably 10,000 or less, more preferably 600 or less, still more preferably from 200 to 550. When the Mw is less than 200, its volatility tends to increase to lower the handleability of a cast film/sheet as one form of the curable resin composition. Meanwhile, when the Mw is more than 10,000, the cast film/sheet is liable to be stiff and brittle, and besides, the adhesive property of a cured article of the cast film/sheet tends to decrease. Herein, the cast film/sheet refers to a film or a sheet of the curable resin composition obtained by dissolving the curable resin composition in a solvent to prepare a varnish, and forming the varnish into a film so as to have a thickness of from several micrometers to several millimeters, followed by drying.

The content of the component (D) in the curable resin composition is preferably from 0.1 mol to 1.5 mol with respect to 1 mol of the ester bond in the aromatic polyester. The component (D) is more preferably blended in such an amount that its content may be from 0.2 mol to 1.0 mol, most preferably from 0.3 mol to 0.94 mol. When the content falls outside the range, the curing reaction of the epoxy resin by the aromatic polyester does not sufficiently proceed, and effects on a dielectric loss tangent and a glass transition temperature become insufficient. When the content of the component (D) satisfies the above-mentioned preferred lower limit, the adhesive property of the cured article of the cast film/sheet can be additionally enhanced, and when the content satisfies the above-mentioned preferred upper limit, the handleability of the cast film/sheet in an uncured state is additionally enhanced.

In addition, a curing accelerator may be added as a component (E) to the curable resin composition of the present invention in order to adjust, for example, a curing rate or the physical properties of a cured article.

The content of the component (E) is not particularly limited, but the blending amount of the curing accelerator preferably falls within the range of from 0.01 wt % to 5 wt % with respect to 100 wt % of the total of the aromatic polyester and the epoxy resin as the component (D). When the blending amount of the curing accelerator is less than 0.01 wt %, the curing reaction rate becomes low, and when the blending amount is more than 5 wt %, self-polymerization of the epoxy resin (D) may occur to inhibit the curing reaction of the epoxy resin by the aromatic polyester (A).

The curing accelerator as the component (E) is not particularly limited. Specific examples thereof include a tertiary amine, an imidazole, an imidazoline, a triazine, an organic phosphorus-based compound, and diazabicycloalkenes such as a quaternary phosphonium salt and an organic acid salt. The examples further include an organometallic compound, a quaternary ammonium salt, and a metal halide, and examples of the organometallic compound include zinc octylate, tin octylate, and an aluminum acetylacetone complex.

As the component (E), there may also be used an imidazole curing accelerator having a high melting point, a dispersion-type latent curing accelerator having a high melting point, a microcapsule-type latent curing accelerator, an amine salt-type latent curing accelerator, a high-temperature dissociation-type and thermal cationic polymerization-type latent curing accelerator, or the like. One kind of the curing accelerators may be used alone, or two or more kinds thereof may be used in combination.

In addition, the organophosphorus compound or the imidazole-based curing accelerator having a high melting point is preferred. The use of the organophosphorus compound or the imidazole-based curing accelerator having a high melting point facilitates the control of the curing properties of the curable resin composition, such as the curing rate of the cast film/sheet, and additionally facilitates the adjustment of, for example, the physical properties of a cured article of the curable resin composition, such as the cast film/sheet. The melting point of the curing accelerator is preferably 100° C. or more because of excellent handleability.

In addition, a high-molecular-weight resin may be added at the component (F) to the curable resin composition of the present invention. The structure of the high-molecular-weight resin is not particularly limited as long as its Mw is 10,000 or more. In addition, one kind of high-molecular-weight resin may be used alone, or two or more kinds of high-molecular-weight resins may be used in combination.

Specific examples of the high-molecular-weight resin as the component (F) may include a polyphenylene sulfide resin, a polyarylate resin, a polysulfone resin, a polyether sulfone resin, a polyphenylene ether resin, a polycarbonate resin, a polyvinyl acetal resin, a polyimide resin, a polyamide imide resin, a polybenzoxazole resin, a styrene-based resin, a (meth)acrylic resin, a polycyclopentadiene resin, a polycycloolefin resin, a polyether ether ketone resin, a polyether ketone resin, a polyester resin except the aromatic polyester, known thermoplastic elastomers such as a styrene-ethylene-propylene copolymer, a styrene-ethylene-butylene copolymer, a styrene-butadiene copolymer, a styrene-isoprene copolymer, a hydrogenated styrene-butadiene copolymer, and a hydrogenated styrene-isoprene copolymer, and rubbers such as a resin, e.g., polybutadiene or polyisoprene. Of those, the following resin is preferred from the viewpoints of compatibility with the aromatic polyester and adhesiveness reliability: a polysulfone resin, a polyether sulfone resin, a polyphenylene ether resin, a polycycloolefin resin, a hydrogenated styrene-butadiene copolymer, a hydrogenated styrene-isoprene copolymer, a polyimide resin, a polyamide imide resin, a polyether imide resin, a polycarbonate resin, a polyether ether ketone resin, a polyester resin except the aromatic polyester, or the like.

The preferred lower limit of the glass transition temperature (Tg) of the high-molecular-weight resin as the component (F) is −40° C., its more preferred lower limit is 50° C., and its most preferred lower limit is 90° C. Its preferred upper limit is 250° C., and its more preferred upper limit is 200° C. When the Tg satisfies the preferred lower limit, the resin hardly undergoes thermal degradation. When the Tg satisfies the preferred upper limit, compatibility between the component (F) and the other resins is enhanced. As a result, the handleability of the cast film/sheet in an uncured state, and the heat resistance of the cured article of the cast film/sheet can be additionally enhanced.

The Mw of the high-molecular-weight resin is 10,000 or more, and its preferred lower limit is 20,000, its more preferred lower limit is 30,000, its preferred upper limit is 1,000,000, and its more preferred upper limit is 250,000. When the Mw satisfies the preferred lower limit, the insulating sheet hardly undergoes thermal degradation. When the Mw satisfies the preferred upper limit, compatibility between the high-molecular-weight resin as the component (F) and the other resins is enhanced. As a result, the handleability of the cast film/sheet in an uncured state, and the heat resistance of the cured article of the cast film/sheet can be additionally enhanced.

A curable resin composition containing the component (F) can be easily processed into the cast film/sheet. When the total of the resin components contained in the cast film/sheet (including the components (A), (D), and (F), and any other resin component) is defined as 100 wt %, the content of the component (F) preferably falls within the range of from 10 wt % to 60 wt %. Its lower limit is preferably 20 wt %, and its upper limit is more preferably 50 wt %. When the content is 10 wt % or more, the handleability of the cast film/sheet in an uncured state can be additionally enhanced. When the content is 60 wt % or less, the dispersion of the component (G) is facilitated.

In addition, an inorganic filler may be added as the component (G) in order to further decrease the thermal expansion rate of each of a cured article, a curable composite material, a composite material cured article, a laminated body, an electrical and electronic part, and a circuit board to be obtained from the curable resin composition. Examples of the inorganic filler include silica, alumina, barium sulfate, talc, clay, mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, and calcium zirconate. Of those, a silica such as amorphous silica, fused silica, crystalline silica, or synthetic silica is particularly suitable. A spherical silica is preferred as the silica. Two or more kinds of those fillers may be used in combination.

The average particle diameter of the component (G) is not particularly limited. From the viewpoint of the formation of fine wiring on the insulating layer, the average particle diameter is preferably 5 μm or less, more preferably 1 μm or less, still more preferably 0.7 μm or less. When the average particle diameter is excessively small, in the case of preparing the curable resin composition of the present invention into a resin varnish, such as a varnish for a circuit board material, the viscosity of the varnish tends to increase to lower its handleability. Accordingly, the average particle diameter is preferably 0.05 μm or more. The average particle diameter may be measured by a laser diffraction/scattering method based on Mie scattering theory. Specifically, the average particle diameter may be measured by producing the particle size distribution of the inorganic filler on a volume basis with a laser diffraction-type particle size distribution measuring apparatus, and adopting its median diameter as the average particle diameter. As a measurement sample, there may be preferably used one obtained by dispersing the inorganic filler in water by ultrasonication. LA-500 manufactured by Horiba, Ltd. or the like may be used as the laser diffraction-type particle size distribution measuring apparatus.

The component (G) is preferably one subjected to surface treatment with a surface treatment agent, such as an epoxysilane coupling agent, an aminosilane coupling agent, or a titanate-based coupling agent. This is because moisture resistance is improved. The blending amount of the component (G) falls within preferably the range of from 10 mass % to 80 mass %, more preferably the range of from 15 mass % to 70 mass %, still more preferably the range of from 20 mass % to 65 mass % with respect to 100 mass % of the non-volatile content of the curable resin composition of the present invention. When the blending amount of the component (G) is more than 80 mass %, the cured article tends to be brittle, and peel strength tends to decrease. Meanwhile, when the blending amount is less than 10 mass %, an effect of the blending is not sufficiently expressed.

In addition, the curable resin composition of the present invention may contain a flame retardant as a component (H) as long as the effects of the present invention are not impaired. Examples of the flame retardant include an organic phosphorus-based flame retardant, an organic nitrogen-containing phosphorus compound, a nitrogen compound, a silicone-based flame retardant, and a metal hydroxide. Examples of the organic phosphorus-based flame retardant include: phenanthrene-type phosphorus compounds such as HCA, HCA-HQ, and HCA-NQ manufactured by Sanko Co., Ltd.; a phosphorus-containing benzoxazine compound such as HFB-2006M manufactured by Showa Highpolymer Co., Ltd.; phosphoric acid ester compounds such as REOFOS 30, 50, 65, 90, 110, TPP, RPD, BAPP, CPD, TCP, TXP, TBP, TOP, KP140, or TIBP manufactured by Ajinomoto Fine-Techno Co., Inc., PPQ manufactured by Hokko Sangyo Co., Ltd., OP930 manufactured by Clariant, and PX200 manufactured by Daihachi Chemical Industry Co., Ltd.; phosphorus-containing epoxy resins such as FX-289 and FX-305 manufactured by Tohto Kasei Co., Ltd.; a phosphorus-containing phenoxy resin such as ERF-001 manufactured by Tohto Kasei Co., Ltd.; and a phosphorus-containing epoxy resin such as YL7613 manufactured by Japan Epoxy Resin Co., Ltd. Examples of the organic nitrogen-containing phosphorus compound include: phosphoric acid ester amide compounds such as SP670 and SP703 manufactured by Shikoku Chemicals Corporation; and phosphazene compounds such as SPB-100 and SPE-100 manufactured by Otsuka Chemical Co., Ltd., and an FP-series manufactured by Fushimi Pharmaceutical Co., Ltd. Examples of the metal hydroxide include: magnesium hydroxide such as UD-65, UD-650, or UD-653 manufactured by Ube Material Industries, Ltd.; and aluminum hydroxide such as B-30, B-325, B-315, B-308, B-303, or UFH-20 manufactured by Tomoe Engineering Co., Ltd.

The blending amount of the component (H) falls within preferably the range of from 10 parts by weight to 400 parts by weight, more preferably the range of from 20 parts by weight to 300 parts by weight with respect to 100 parts by weight of the resin components.

The curable resin composition of the present invention may contain a thermosetting resin having a Mw of less than 10,000 different from the aromatic polyester as the component (A) and the component (D) as long as the effects of the present invention are not impaired. Examples of the thermosetting resin having a Mw of less than 10,000 may include: a polymerized product of a bismaleimide compound and a diamine compound; a bisallylnadide resin; a benzoxazine compound; and a benzocyclobutene compound. Two or more kinds thereof may be used as a mixture.

The curable resin composition of the present invention may contain a phenoxy resin. When the phenoxy resin is blended, curing is accelerated to improve the thermal curing property of the curable resin composition. The phenoxy resin is a polymer formed of a reaction product of a bifunctional epoxy resin and a bisphenol compound, and shows a curing-accelerating action on the aromatic polyester. Accordingly, it is considered that a relatively low curing temperature allows sufficient curing physical properties (such as heat resistance and a low dielectric loss tangent) to be exhibited. In addition, the blending of the phenoxy resin improves the roughening property of the cured article by an oxidizing agent, and also improves adhesiveness with a conductor layer formed by plating.

In addition, a phenoxy resin having an epoxy group remaining at an end subjected to a reaction with (meth)acrylic acid, or a phenoxy resin having part of its hydroxyl groups subjected to a reaction with a methacrylate compound or an acrylate compound having an isocyanate group may also be used. In this case, those phenoxy resins function also as radically polymerizable resins.

Preferred examples of the phenoxy resin include PHENOTOHTO YP50 (manufactured by Tohto Kasei Co., Ltd.) and E-1256 (manufactured by Japan Epoxy Resin Co., Ltd.), which are bisphenol A-type phenoxy resins, and PHENOTOHTO YPB40 (manufactured by Tohto Kasei Co., Ltd.), which is a brominated phenoxy resin. A phenoxy resin having a biphenyl skeleton is particularly preferred from the viewpoints of heat resistance, moisture resistance, and a curing-accelerating action. Specific examples of such phenoxy resin may include YL6742BH30, YL6835BH40, YL6953BH30, YL6954BH30, YL6974BH30, and YX8100BH30, each of which is a phenoxy resin formed of a reaction product of a biphenyl-type epoxy resin (YX4000 manufactured by Japan Epoxy Resin Co., Ltd.) and any of various bisphenol compounds. Each of those phenoxy resins may be used alone, or two or more kinds thereof may be used in combination.

The phenoxy resin improves the flexibility of an adhesive film as well as the curing-accelerating action, to facilitate the handling thereof, and also improves the mechanical strength and the flexibility of the cured article. A phenoxy resin having a weight-average molecular weight of from 5,000 to 100,000 may be preferably used as the phenoxy resin. When the weight-average molecular weight of the phenoxy resin is less than 5,000, the above-mentioned effects are not sufficient in some cases, and when the weight-average molecular weight of the phenoxy resin is more than 100,000, its solubility in each of the epoxy resin and the organic solvent is markedly decreased to make practical use difficult in some cases.

Although the blending amount of the phenoxy resin varies depending on its kind, the phenoxy resin is preferably blended in an amount in the range of from 3 parts by weight to 40 parts by weight with respect to 100 parts by weight of the total amount of the aromatic polyester and the epoxy resin. The phenoxy resin is particularly preferably blended in an amount in the range of from 5 parts by weight to 25 parts by weight. When the blending amount is less than 3 parts by weight, the curing-accelerating action on the resin composition is not sufficient in some cases, and in the lamination of the resin composition on a circuit board, or in the thermal curing of the laminated resin composition, the fluidity of the resin tends to become so high that the thickness of the insulating layer becomes nonuniform. In addition, the roughening property of the cured article for conductor layer formation tends to be difficult to obtain. Meanwhile, when the blending amount is more than 40 parts by weight, a functional group of the phenoxy resin is present in an excess amount, with the result that a sufficiently low dielectric loss tangent value tends not to be obtained, and besides, the fluidity in the lamination of the adhesive film on the circuit board tends to be so low that a via hole or a through hole present in the circuit board cannot be sufficiently filled with the resin. It should be noted that when the Mw of the phenoxy resin is 10,000 or more, the phenoxy resin also corresponds to the component (F), but the blending amount of the phenoxy resin as a whole is preferably set to the above-mentioned blending amount.

A varnish for a circuit board material of the present invention may be produced by dissolving the curable resin composition in a solvent. Examples of the organic solvent that may be used here include methyl ethyl ketone, acetone, toluene, xylene, tetrahydrofuran, dioxolane, dimethylformamide, methyl isobutyl ketone, methoxypropanol, cyclohexanone, methylcellosolve, ethyl diglycol acetate, and propylene glycol monomethyl ether acetate. Its selection or suitable use amount may appropriately be selected depended on its application. For example, in a printed wiring board application, a solvent having a boiling point of 160° C. or less, such as methyl ethyl ketone, acetone, toluene, xylene, or 1-methoxy-2-propanol, is preferred, and the solvent is preferably used at such a ratio that a non-volatile content of from 20 mass % to 80 mass % is achieved. Meanwhile, for example, the following organic solvent is preferably used as the organic solvent for an application to an adhesive film for building up: a ketone such as acetone, methyl ethyl ketone, or cyclohexanone; an acetate such as ethyl acetate, butyl acetate, cellosolve acetate, propylene glycol monomethyl ether acetate, or carbitol acetate; cellosolve; a carbitol such as butylcarbitol; an aromatic hydrocarbon such as toluene or xylene; dimethylformamide; dimethylacetamide; or N-methylpyrrolidone. In addition, the solvent is preferably used at such a ratio that a non-volatile content of from 20 mass % to 80 mass % is achieved. Through the curing of the varnish for a circuit board material, a circuit board of the present invention can be obtained in an advantageous manner. Specific examples of the circuit board include a printed wiring board, a printed circuit board, a flexible printed wiring board, and a build-up wiring board.

A cured article obtained by curing the curable resin composition of the present invention may be used as a molded article, a laminated article, a cast article, an adhesive, a coating, a film, or a sheet depending on applications. For example, in a semiconductor sealing material application, the cured article is a cast article or a molded article, and the cured article may be obtained by: casting the curable resin composition, or molding the curable resin composition using a transfer molding machine, an injection machine, or the like; and heating the resultant at from 80° C. to 230° C. for from 0.5 hr to 10 hr. In addition, in a circuit board application, the cured article is a laminated article, and the cured article may be obtained by: impregnating a base material, such as glass fiber, carbon fiber, polyester fiber, polyamide fiber, alumina fiber, or paper, with the varnish for a circuit board material; drying the resultant by heating to provide a prepreg (curable composite material); and laminating two or more of the prepreg together to provide a laminated article of the curable composite material, or laminating the prepreg with a metal foil, such as a copper foil, to provide a metal foil with a resin, followed by heat press molding.

In addition, inorganic high-dielectric powder, such as barium titanate, or an inorganic magnetic material, such as a ferrite, may be blended in the curable resin composition of the present invention. With this, the curable resin composition of the present invention is useful as a material for an electrical and electronic part, in particular, a high frequency electronic part material.

In addition, like a curable composite material to be described later, the curable resin composition of the present invention may be used as a metal foil with a resin or a laminated body by being bonded or applied to a metal foil (including a metal plate. The same applies hereinafter.).

Next, a curable composite material and a cured body thereof of the present invention are described. In the curable composite material, a base material is used in order to enhance mechanical strength and improve dimensional stability.

Examples of such base material include fabrics or papers including: various glass fabrics such as a roving cloth, a cloth, a chopped mat, and a surfacing mat; asbestos fabrics; metal fiber fabrics and any other synthetic or natural inorganic fiber fabrics; woven fabrics or non-woven fabrics each obtained from a liquid crystal fiber such as a wholly aromatic polyamide fiber, a wholly aromatic polyester fiber, or a polybenzazole fiber; woven fabrics or non-woven fabrics each obtained from a synthetic fiber such as a polyvinyl alcohol fiber, a polyester fiber, or an acrylic fiber; natural fiber fabrics such as a cotton fabric, a hemp fabric, or a felt; and natural cellulose-based fabrics such as a carbon fiber fabric, kraft paper, cotton paper, or paper-glass-mixed fiber paper. Each of those base materials is used alone, or two or more kinds thereof are used in combination.

The ratio of the base material in the curable composite material is from 5 wt % to 90 wt %, preferably from 10 wt % to 80 wt %, more preferably from 20 wt % to 70 wt % in the curable composite material. When the ratio of the base material is less than 5 wt %, dimensional stability and strength after the curing of the curable composite material tend to decrease. In addition, when the ratio of the base material is more than 90 wt %, the dielectric characteristics of the curable composite material tend to lower.

In the curable composite material of the present invention, as necessary, a coupling agent may be used for the purpose of improving an adhesive property at an interface between the resin and the base material. As the coupling agent, there may be used a general coupling agent, such as a silane coupling agent, a titanate coupling agent, an aluminum-based coupling agent, or a zircoaluminate coupling agent.

As a method of producing the curable composite material of the present invention, for example, there is given a method involving homogeneously dissolving or dispersing the curable resin composition of the present invention (any other component may be added as necessary) in the solvent to be used for the varnish for a circuit board material or a mixed solvent thereof, and impregnating the base material with the resultant, followed by drying. The impregnation is performed by dipping, application, or the like. The impregnation may be repeated multiple times as necessary, and the impregnation may be repeated using multiple solutions different from each other in composition or concentration to finally adjust the resin composition and the resin amount to desired ones.

A composite material cured article is obtained by curing the curable composite material of the present invention by a method such as heating. A production method therefor is not particularly limited, and for example, a composite material cured article having a desired thickness may be obtained by laminating multiple pieces of the curable composite material, and simultaneously performing heating and pressurization to bond the multiple pieces while simultaneously performing curing with heat or the like. In addition, the curable composite material may be further laminated on the composite material cured article, bonded thereto, and cured to provide a composite material cured article having a new layer structure. The lamination, the bonding, and the curing are generally simultaneously performed using, for example, a heat press, such as a vacuum laminator, but a step for the lamination and the bonding, and a step for the curing may each be performed separately. That is, an uncured or semi-cured composite material obtained in advance by the lamination and the bonding may be cured through heat treatment or treatment by another method.

In the case of being simultaneously performed, the lamination, the bonding, and the curing may be performed in the ranges of a temperature of from 80° C. to 300° C., a pressure of from 0.1 kg/cm² to 1,000 kg/cm², and a period of time of from 1 min to 10 hr, more preferably the ranges of a temperature of from 100° C. to 250° C., a pressure of from 1 kg/cm² to 500 kg/cm², and a period of time of from 1 min to 5 hr.

A laminated body of the present invention includes a layer of the composite material cured article and a layer of a metal foil. Examples of the metal foil to be used in this case include a copper foil and an aluminum foil. The thickness of the metal foil to be used in the present invention is not particularly limited, but falls within the range of preferably from 1 μm to 50 μm, more preferably from 3 μm to 35 μm. In addition, the thickness of the laminated body falls within the range of from 20 μm to 5,000 μm.

As a method of producing the laminated body of the present invention, for example, there may be given a method involving laminating the curable composite material of the present invention and the metal foil with a layer structure appropriate for a purpose, and simultaneously performing heating and pressurization to bond the layers to each other while simultaneously performing thermal curing. In the laminated body of the present invention, the composite material cured article and the metal foil are laminated with an arbitrary layer structure. The metal foil may be used as any of a surface layer and an intermediate layer. In addition, the lamination of the curable composite material and the metal foil, and the curing may be repeated multiple times to form a multilayer structure.

An adhesive may be used for the bonding of the curable composite material and the metal foil. Examples of the adhesive include, but are not particularly limited to, an epoxy-based adhesive, an acrylic adhesive, a phenol-based adhesive, and a cyanoacrylate-based adhesive. The lamination and the bonding, and the curing may be performed under similar conditions to those in the production of the composite material cured article of the present invention.

In addition, the curable resin composition of the present invention may be molded into a film shape. This is preferred because when molded into a film shape, the curable resin composition can be easily processed into an electrical and electronic part or the like. The thickness of the film is not particularly limited, but is preferably from 3 μm to 200 μm, more preferably from 5 μm to 105 μm.

A method of producing the film is not particularly limited, and an example thereof is a method involving homogeneously dissolving or dispersing the curable resin composition, and as necessary, any other component in, for example, an aromatic or ketone-based solvent or a mixed solvent thereof, and applying the resultant to a resin film, such as a PET film, followed by drying. The application may be repeated multiple times as necessary, and in this case, the application may be repeated using multiple solutions different from each other in composition or concentration to finally adjust the resin composition and the resin amount to desired ones.

A metal foil with a resin of the present invention includes the curable resin composition of the present invention and a metal foil. Examples of the metal foil to be used in this case include a copper foil and an aluminum foil. The thickness of the metal foil with a resin is not particularly limited, but falls within the range of preferably from 3 μm to 200 μm, more preferably from 5 μm to 105 μm. In addition, the thickness of the metal foil falls within the range of from 1 μm to 50 μm.

A method of producing the metal foil with a resin of the present invention is not particularly limited, and an example thereof is a method involving homogeneously dissolving or dispersing the curable resin composition (any other component may be added as necessary) in the solvent to be used for the varnish for a circuit board material or a mixed solvent thereof, and applying the resultant to the metal foil, followed by drying. The application may be repeated multiple times as necessary, and in this case, the application may be repeated using multiple solutions different from each other in composition or concentration to finally adjust the resin composition and the resin amount to desired ones.

In addition, in the present invention, the curable resin composition molded into a film shape (hereinafter referred to as “film”) may be used as an adhesive layer to provide a laminated film including the adhesive layer and a layer to be plated formed of a resin composition for a layer to be plated to be described later.

As a method of producing the laminated film, for example, the following two methods are given. A production method (1) is a production method involving applying, spraying, or casting the resin composition for a layer to be plated onto a support, followed, as necessary, by drying, and then further applying or casting the curable resin composition thereonto, followed, as necessary, by drying. A production method (2) is a production method involving applying, spraying, or casting the resin composition for a layer to be plated onto a support, followed, as necessary, by drying, then applying, spraying, or casting the curable resin composition onto another support, followed, as necessary, by drying, and laminating and integrating them. Of those production methods, the production method (1) is preferred because the production method (1) is the easier process and is excellent in productivity.

In the production methods (1) and (2), it is preferred that an organic solvent be added to the curable resin composition or the resin composition for a layer to be plated so as to prepare a varnish and then the varnish be applied, sprayed, or cast.

Examples of the support include a resin film and a metal foil. Examples of the resin film include a polyethylene terephthalate film, a polypropylene film, a polyethylene film, a polycarbonate film, a polyethylene naphthalate film, a polyarylate film, and a nylon film. Of those films, a polyethylene terephthalate film or a polyethylene naphthalate film is preferred from the viewpoints of heat resistance, chemical resistance, peelability, and the like. Examples of the metal foil include a copper foil, an aluminum foil, a nickel foil, a chromium foil, a gold foil, and a silver foil. It should be noted that the surface average roughness Ra of the support is generally 300 nm or less, preferably 150 nm or less, more preferably 100 nm or less.

In the production methods (1) and (2), the thicknesses of the resin composition for a layer to be plated and the curable resin composition are not particularly limited, but when the laminated film is produced, the thickness of the layer to be plated is preferably from 1 μm to 10 μm, more preferably from 1.5 μm to 8 μm, still more preferably from 2 μm to 5 μm. In addition, the thickness of the adhesive layer is preferably from 10 μm to 100 μm, more preferably from 10 μm to 80 μm, still more preferably from 15 μm to 60 μm. When the thickness of the layer to be plated is less than 1 μm, in the case of forming a conductor layer by electroless plating on the cured article to be obtained by curing the laminated film, there is a risk in that the formability of the conductor layer may be lowered. Meanwhile, when the thickness of the layer to be plated is more than 100 μm, there is a risk in that the linear expansion of the cured article to be obtained by curing the laminated film may enlarge. In addition, when the thickness of the adhesive layer is less than 10 μm, there is a risk in that the wire embedding property of the laminated film may be lowered.

As methods of applying the resin composition for a layer to be plated and the curable resin composition, there are given, for example, dip coating, roll coating, curtain coating, die coating, slit coating, and gravure coating.

In addition, drying may be performed as necessary after the resin composition for a layer to be plated has been applied, sprayed, or cast onto the support, or after the curable resin composition has been applied, sprayed, or cast onto the resin composition for a layer to be plated in the production method (1), or after the resin composition for a layer to be plated and the curable resin composition have been applied onto the support in the production method (2). A drying temperature is set to preferably a temperature at which the resin composition for a layer to be plated and the curable resin composition are not cured, more preferably from 20° C. to 300° C., still more preferably from 30° C. to 200° C. In addition, a drying time is generally from 30 sec to 1 hr, preferably from 1 min to 30 min.

It should be noted that in the laminated film, the layer to be plated and the adhesive layer are each preferably in an uncured or semi-cured state. With this, the adhesive layer included in the laminated film can be one having a high adhesive property.

The curable composite material of the present invention is formed of the curable resin composition of the present invention and a base material. For example, a fibrous base material (hereinafter referred to as “fiber base material”) impregnated with the curable resin composition is a prepreg as one kind of the curable composite material. The prepreg generally has a sheet-shaped or film-shaped form.

Examples of the fiber base material to be used in this case include: organic fiber, such as polyamide fiber, polyaramid fiber, or polyester fiber; and inorganic fiber, such as glass fiber or carbon fiber. In addition, examples of the form of the fiber base material include: a woven fabric form which is, for example, plain-woven or twill-woven; and a non-woven fabric form. The thickness of the fiber base material is preferably from 5 μm to 100 μm, and the range of from 10 μm to 50 μm is preferred. When the thickness is less than 5 μm, the fiber base material is difficult to handle, and when the thickness is more than 100 μm, the resin layer is relatively thin and the wire embedding property is insufficient in some cases.

In addition, the amount of the fiber base material in the prepreg is generally from 20 wt % to 90 wt %, preferably from 30 wt % to 85 wt %.

A method of impregnating the fiber base material with the curable resin composition of the present invention is not particularly limited, and examples thereof include: a method involving adding an organic solvent to the curable resin composition of the present invention in order to adjust viscosity or the like, and dipping the fiber base material in the resultant; and a method involving applying or spraying the curable resin composition to which an organic solvent has been added to the fiber base material. For example, the fiber base material is placed on a support, and the curable resin composition to which an organic solvent has been added is applied or sprayed thereto. It should be noted that in the prepreg, the curable resin composition is preferably in an uncured or semi-cured state.

In addition, after the impregnation of the fiber base material with the curable resin composition, the resultant may be dried as necessary. A drying temperature is set to preferably a temperature at which the curable resin composition of the present invention is not cured, more preferably from 20° C. to 300° C., still more preferably from 30° C. to 200° C. When the drying temperature is more than 300° C., there is a risk in that the curing reaction may proceed excessively to prevent the prepreg to be obtained from achieving an uncured or semi-cured state. In addition, a drying time is preferably from 30 sec to 1 hr, more preferably from 1 min to 30 min.

In addition, the prepreg may be one formed of the laminated film and a fiber base material. In this case, one surface of the prepreg is the adhesive layer, the other surface is the layer to be plated, and the fiber base material is present inside these layers. In this case as well, the same fiber base material as that described above may be used as the fiber base material.

In addition, a method of producing such prepreg is not particularly limited, and for example, the following three production methods are given. A production method (1) is a production method involving preparing two supports, laminating the curable resin composition for an adhesive layer on one of the supports, laminating the resin composition for a plating layer on the other support, and laminating them with their resin composition sides opposed to each other and the fiber base material sandwiched therebetween, under, as necessary, for example, a pressurized, vacuum, or heated condition. A production method (2) is a production method involving impregnating the fiber base material with any one of the curable resin composition for an adhesive layer or the resin composition for a layer to be plated, followed, as necessary, by drying, to produce a prepreg, and directly applying, spraying, or casting the other resin composition onto the prepreg, or laminating the other resin composition on a support and laminating the resultant on the prepreg with their resin composition layer sides opposed to each other. A production method (3) is a production method involving laminating any one of the curable resin composition for an adhesive layer or the resin composition for a layer to be plated on a support by application, spraying, casting, or the like, placing the fiber base material thereon, and laminating the other resin composition on the resultant by application, spraying, or casting, followed, as necessary, by drying. It should be noted that in each of the methods, it is preferred to add an organic solvent to each resin composition as necessary to adjust the viscosity of the resin composition, thereby controlling workability in the impregnation of the fiber base material or in the application, the spraying, or the casting onto the support. In addition, as methods of applying the resin composition for a layer to be plated and the curable resin composition, there are given, for example, dip coating, roll coating, curtain coating, die coating, slit coating, and gravure coating.

Examples of the support used in this case include: resin films such as a polyethylene terephthalate film, a polypropylene film, a polyethylene film, a polycarbonate film, a polyethylene naphthalate film, a polyarylate film, and a nylon film; and metal foils such as a copper foil, an aluminum foil, a nickel foil, a chromium foil, a gold foil, and a silver foil. Anyone of those supports may be attached to one surface, or each of both surfaces, of the prepreg.

The thickness of the prepreg formed of the laminated film and the fiber base material is not particularly limited, but the thickness may be as described below. The thickness of the layer to be plated is preferably from 1 μm to 10 μm, more preferably from 1.5 μm to 8 μm, still more preferably from 2 μm to 5 μm. In addition, the thickness of the adhesive layer is preferably from 10 μm to 100 μm, more preferably from 10 μm to 80 μm, still more preferably from 15 μm to 60 μm.

In addition, when the curable composite material of the present invention (prepreg) is one formed of the laminated film and the fiber base material, the resin compositions forming the layer to be plated and the adhesive layer are each preferably in an uncured or semi-cured state as in the laminated film.

Then, the composite material cured article may be obtained by heating and curing the curable composite material of the present invention obtained as described above.

A curing temperature is generally from 30° C. to 400° C., preferably from 70° C. to 300° C., more preferably from 100° C. to 200° C. In addition, a curing time is from 0.1 hr to 5 hr, preferably from 0.5 hr to 3 hr. A method for the heating is not particularly limited, and for example, it is appropriate to perform the heating using an electric oven.

The laminated body of the present invention includes the curable resin composition or the curable composite material of the present invention (hereinafter collectively referred to as “electrically insulating layer precursor”) laminated on a substrate.

The substrate is preferably a substrate having a conductor layer on its surface. It should be noted that when the electrically insulating layer precursor is the laminated film or the prepreg formed of the laminated film and the fiber base material, the electrically insulating layer precursor is laminated so that the adhesive layer of the laminated film and the substrate may be brought into contact with each other.

The substrate having a conductor layer on its surface is such that the conductor layer is present on the surface of an electrically insulating substrate. The electrically insulating substrate is formed by curing a resin composition containing a known electrically insulating material (such as an alicyclic olefin polymer, an epoxy resin, a maleimide resin, a (meth)acrylic resin, a diallyl phthalate resin, a triazine resin, polyphenyl ether, or glass). The conductor layer is not particularly limited, but is generally a layer containing wiring formed of a conductive material, such as a conductive metal, and the layer may further contain any of various circuits. The structure, thickness, and the like of each of the wiring and the circuits are not particularly limited. Specific examples of the substrate having a conductor layer on its surface may include a printed wiring board and a silicon wafer substrate. The thickness of the substrate having a conductor layer on its surface is generally from 10 μm to 10 mm, preferably from 20 μm to 5 mm, more preferably from 30 μm to 2 mm.

The conductor layer surface of the substrate having a conductor layer on its surface is preferably subjected to pretreatment in order to improve adhesiveness with the electrically insulating layer. As a method for the pretreatment, a known technology may be used without any particular limitation. For example, when the conductor layer is formed of copper, examples of the method include: an oxidation treatment method involving bringing a strong alkali oxidizing solution into contact with the conductor layer surface to forma copper oxide layer on the conductor surface, thereby roughening the surface; a method involving oxidizing the conductor layer surface by the above-mentioned method, and then reducing the surface with sodium borohydride, formalin, or the like; a method involving depositing plating onto the conductor layer to roughen the surface; a method involving bringing an organic acid into contact with the conductor layer to dissolve a copper grain boundary, thereby roughening the surface; and a method involving forming a primer layer on the conductor layer through the use of a thiol compound, a silane compound, or the like. Of those, from the viewpoint of the ease of maintenance of the shape of a fine wiring pattern, a method involving bringing an organic acid into contact with the conductor layer to dissolve a copper grain boundary, thereby roughening the surface, and a method involving forming a primer layer through the use of a thiol compound, a silane compound, or the like are preferred.

In addition, a metal foil, such as a copper foil, an aluminum foil, or an iron foil, may be used as the substrate. For example, when the curable resin composition is laminated on a copper foil, a copper foil with a resin is obtained.

The laminated body of the present invention may be generally produced by thermocompression bonding of the electrically insulating layer precursor onto the substrate having a conductor layer on its surface.

As a method for the thermocompression bonding, there is given a method involving placing the electrically insulating layer precursor with a support on and in contact with the conductor layer of the substrate, and subjecting the resultant to thermocompression bonding (lamination) through the use of a pressurizer, such as a pressure laminator, a press, a vacuum laminator, a vacuum press, or a roll laminator. As a result of the thermocompression bonding, the conductor layer on the substrate surface and the electrically insulating layer precursor can be bonded to each other so that substantially no void may be present at an interface therebetween. It should be noted that in this case, when the electrically insulating layer precursor is the laminated film or the prepreg formed of the laminated film and the fiber base material, the thermocompression bonding is performed under a state in which the adhesive layer of the electrically insulating layer precursor is placed on and in contact with the conductor layer of the substrate.

The thermocompression bonding is performed at a temperature of generally from 30° C. to 250° C., preferably from 70° C. to 200° C., with a pressure to be applied of generally from 10 kPa to 20 MPa, preferably from 100 kPa to 10 MPa, for a period of time of generally from 30 sec to 5 hr, preferably from 1 min to 3 hr. In addition, the thermocompression bonding is preferably performed under reduced pressure in order to improve a wiring pattern embedding property and suppress the generation of air bubbles. Specifically, the reduced pressure is generally from 100 kPa to 1 Pa, preferably from 40 kPa to 10 Pa.

In addition, two or more layers of the electrically insulating layer precursor may be laminated on the conductor layer of the substrate for the purpose of improving the flatness of the electrically insulating layer, or for the purpose of increasing the thickness of the electrically insulating layer.

The laminated body of the present invention may be converted to a cured article laminated body by converting the electrically insulating layer precursor to an electrically insulating layer through treatment for curing the electrically insulating layer precursor. The curing is generally performed by heating the entirety of the laminated body. In addition, the curing may be simultaneously performed with the thermocompression bonding of the electrically insulating layer precursor and the substrate in the production of the laminated body.

A curing temperature is generally from 30° C. to 400° C., preferably from 70° C. to 300° C., more preferably from 100° C. to 200° C. In addition, a curing time is from 0.1 hr to 5 hr, preferably from 0.5 hr to 3 hr. A method for the heating is not particularly limited, and for example, it is appropriate to perform the heating using an electric oven.

In addition, another conductor layer (hereinafter referred to as “conductor layer 2”) may be further formed on the composite material cured article layer of the laminated body of the present invention. Metal plating or a metal foil may be used as the conductor layer 2. In this case, when the electrically insulating layer is the laminated film or the prepreg formed of the laminated film and the fiber base material, the conductor layer 2 is formed on the layer to be plated of the electrically insulating layer.

When a metal plating material is used as the conductor layer 2, examples of the kind of the plating include gold, silver, copper, rhodium, palladium, nickel, and tin. When the metal foil is used, an example thereof is the metal foil for use as the support to be used in the production of the film or the prepreg. It should be noted that in the present invention, a method using the metal plating as the conductor layer is preferred because the method enables fine wiring. Now, a method of producing the composite body is described by taking a multilayer circuit board using metal plating as the conductor layer 2 as an example.

First, a via hole or a through hole which penetrates through the electrically insulating layer is formed in the cured article laminated body. The via hole is formed in order to connect, when a multilayer circuit board is produced, the constituent conductor layers of the multilayer circuit board. The via hole or the through hole may be formed by, for example, chemical treatment, such as a photolithography method, or physical treatment, such as a drill, a laser, or plasma etching. Of those methods, a method based on a laser (such as a carbon dioxide laser, an excimer laser, or a UV-YAG laser) is preferred because a finer via hole can be formed without the lowering of the characteristics of the electrically insulating layer.

Next, surface-roughening treatment for roughening the surface of the electrically insulating layer of the cured article laminated body (that is, the cured article or the composite material cured article of the present invention) is performed. The surface-roughening treatment is performed in order to enhance an adhesive property with the conductor layer 2 to be formed on the electrically insulating layer.

The surface average roughness Ra of the electrically insulating layer is preferably 0.05 μm or more and less than 0.5 μm, more preferably 0.06 μm or more and 0.3 μm or less, and the lower limit of the surface ten-point average roughness Rzjis of the electrically insulating layer is preferably 0.3 μm or more, more preferably 0.5 μm or more, and the upper limit thereof is preferably less than 6 μm, more preferably 5 μm or less, still more preferably less than 4 μm, particularly preferably 2 μm or less. It should be noted that herein, Ra is an arithmetic average roughness defined in JIS B0601-2001, and the surface ten-point average roughness Rzjis is a ten-point average roughness defined in JIS B0601-2001 Appendix 1.

A method for the surface-roughening treatment is not particularly limited, and an example thereof is a method involving bringing the surface of the electrically insulating layer into contact with an oxidizing compound. Examples of the oxidizing compound include known compounds each having an oxidizing ability, such as an inorganic oxidizing compound and an organic oxidizing compound. From the viewpoint of the ease of control of the surface average roughness of the electrically insulating layer, it is particularly preferred to use an inorganic oxidizing compound or an organic oxidizing compound. Examples of the inorganic oxidizing compound include a permanganate, chromic anhydride, a bichromate, a chromate, a persulfate, active manganese dioxide, osmium tetraoxide, hydrogen peroxide, and a perbromate. Examples of the organic oxidizing compound include dicumyl peroxide, octanoyl peroxide, m-chloroperbenzoic acid, peracetic acid, and ozone.

A method of subjecting the surface of the electrically insulating layer to surface-roughening treatment using an inorganic oxidizing compound or an organic oxidizing compound is not particularly limited. An example thereof is a method involving bringing an oxidizing compound solution prepared by dissolving the oxidizing compound in a solvent capable of dissolving the oxidizing compound into contact with the surface of the electrically insulating layer. A method of bringing the oxidizing compound solution into contact with the surface of the electrically insulating layer is not particularly limited, and may be any method such as: a dip method involving dipping the electrically insulating layer in the oxidizing compound solution; a puddle method involving placing the oxidizing compound solution on the electrically insulating layer through the utilization of the surface tension of the oxidizing compound solution; or a spray method involving spraying the oxidizing compound solution to the electrically insulating layer. As a result of the surface-roughening treatment, adhesiveness between the electrically insulating layer and another layer such as the conductor layer 2 can be improved.

A temperature at which such oxidizing compound solution is brought into contact with the surface of the electrically insulating layer and a period of time for the contact may be arbitrarily set in consideration of, for example, the concentration and the kind of the oxidizing compound, and the contact method. The temperature is generally from 10° C. to 250° C., preferably from 20° C. to 180° C., and the period of time is generally from 0.5 min to 60 min, preferably from 1 min to 40 min.

It should be noted that after the surface-roughening treatment, in order to remove the oxidizing compound, the surface of the electrically insulating layer after the surface-roughening treatment is washed with water. In addition, when a substance which cannot be completely washed off with water alone is attached to the surface, further washing is performed with a washing liquid capable of dissolving the substance, or the substance is converted to a water-soluble substance through, for example, contact with another compound and then washed off with water. For example, when an alkaline aqueous solution, such as a potassium permanganate aqueous solution or a sodium permanganate aqueous solution, is brought into contact with the electrically insulating layer, washing with water may be performed after neutralization reduction treatment with an acidic aqueous solution, such as a mixed liquid of hydroxyamine sulfate and sulfuric acid, for the purpose of removing a generated film of manganese dioxide.

Next, after the electrically insulating layer of the laminated body has been subjected to the surface-roughening treatment, the conductor layer 2 is formed on the surface of the electrically insulating layer, and the inner wall surface of each of the via hole and the through hole.

As a method of forming the conductor layer 2, an electroless plating method is performed from the viewpoint of its capability to form a conductor layer 2 excellent in adhesiveness.

For example, in the formation of the conductor layer 2 by the electroless plating method, the following is generally performed: first, a catalyst nucleus, such as silver, palladium, zinc, or cobalt, is allowed to adhere onto the electrically insulating layer, and then a metal thin film is formed thereon. A method of allowing the catalyst nucleus to adhere onto the electrically insulating layer is not particularly limited, and an example thereof is a method involving dipping the electrically insulating layer in a solution obtained by dissolving a metal compound of, for example, silver, palladium, zinc, or cobalt, or a salt or a complex thereof, in water or an organic solvent, such as an alcohol or chloroform, at a concentration of from 0.001 wt % to 10 wt % (the solution may contain, as necessary, an acid, an alkali, a complexing agent, a reducing agent, or the like), and then reducing the metal.

It is appropriate to use a known self-catalytic electroless plating liquid as an electroless plating liquid to be used in the electroless plating method. The kind of metal, the kind of reducing agent, the kind of complexing agent, the hydrogen ion concentration, the dissolved oxygen concentration, and the like in the plating liquid are not particularly limited. For example, the following electroless plating liquid may be used: an electroless copper plating liquid containing as a reducing agent ammonium hypophosphite, hypophosphorous acid, ammonium borohydride, hydrazine, formalin, or the like; an electroless nickel-phosphorus plating liquid containing as a reducing agent sodium hypophosphite; an electroless nickel-boron plating liquid containing as a reducing agent dimethylamine borane; an electroless palladium plating liquid; an electroless palladium-phosphorus plating liquid containing as a reducing agent sodium hypophosphite; an electroless gold plating liquid; an electroless silver plating liquid; or an electroless nickel-cobalt-phosphorus plating liquid containing as a reducing agent sodium hypophosphite.

After the formation of the metal thin film, the surface of the composite body may be subjected to anti-corrosive treatment through contact with a corrosion inhibitor. In addition, after the formation of the metal thin film, the metal thin film may be heated in order to, for example, improve adhesiveness. A heating temperature is generally from 50° C. to 350° C., preferably from 80° C. to 250° C. It should be noted that in this case, the heating may be performed under a pressurized condition. As a pressurizing method in this case, for example, there is given a method using physical pressurizing means, such as a heat press machine or a pressurizing heating roll machine. A pressure to be applied is generally from 0.1 MPa to 20 MPa, preferably from 0.5 MPa to 10 MPa. When the pressure falls within this range, high adhesiveness between the metal thin film and the electrically insulating layer can be secured.

A resist pattern for plating is formed on the thus formed metal thin film, and further, plating is grown (thick plating) thereon by wet plating, such as electrolytic plating. Then, the resist is removed, and the metal thin film is etched into a pattern shape. Thus, the conductor layer 2 is formed. Therefore, the conductor layer 2 to be formed by this method is generally formed of the metal thin film having a pattern shape and the plating grown thereon.

Alternatively, when the metal foil is used as the conductor layer 2 in the multilayer circuit board in place of the metal plating, the multilayer circuit board may be produced by the following method.

That is, first, in the same manner as above, the cured article laminated body including the electrically insulating layer and the conductor layer formed of the metal foil is prepared. Such cured article laminated body is desirably such that the degree of curing of the curable resin composition allows various required characteristics to be kept when lamination and molding are performed and that no problem arises when subsequent processing is performed or when the multilayer circuit board is produced. The cured article laminated body is particularly desirably formed by performing lamination and molding under vacuum. It should be noted that such cured article laminated body may be used, for example, for a printed wiring board in accordance with a known subtractive method.

Then, in the same manner as above, a via hole or a through hole which penetrates through the electrically insulating layer is formed in the prepared cured article laminated body. Next, in order to remove a resin residue in the formed via hole, the cured article laminated body having the through hole formed therein is subjected to desmear treatment. A method for the desmear treatment is not particularly limited, and an example thereof is a method involving bringing a solution of an oxidizing compound, such as a permanganate, (desmear liquid) into contact with the cured article laminated body. Specifically, the desmear treatment may be performed by dipping the cured article laminated body having the via hole formed therein in an aqueous solution at from 60° C. to 80° C., which has been adjusted so as to have a sodium permanganate concentration of 60 g/L and a sodium hydroxide concentration of 28 g/L, under shaking for from 1 min to 50 min.

Next, after the cured article laminated body has been subjected to the desmear treatment, the conductor layer 2 is formed on the inner wall surface of the via hole. A method of forming the conductor layer 2 is not particularly limited, and any of an electroless plating method and an electrolytic plating method may be used. From the viewpoint of allowing the formation of a conductor layer 2 excellent in adhesiveness, the conductor layer 2 may be formed by the electroless plating method.

Next, after the formation of an electroless plating layer on the inner wall surface of the via hole and on the copper foil, electrolytic plating is performed on the entire surface. Subsequently, a resist pattern is formed on the electrolytic plating layer on the metal foil, and further, the electrolytic plating layer and the metal foil are etched into a pattern shape to form the conductor layer 2. Alternatively, after the formation of the conductor layer 2 on the inner wall surface of the via hole, a resist pattern for plating is formed on the metal foil, and further, plating is grown (thick plating) thereon by wet plating, such as electrolytic plating, and then the resist is removed. Further, the metal foil is etched into a pattern shape to form the conductor layer 2. Therefore, the conductor layer 2 to be formed by this method is generally formed of the metal foil having a pattern shape and the plating grown thereon.

The multilayer circuit board obtained as described above is used as the substrate for the production of the composite body, and the substrate and the electrically insulating layer precursor are subjected to thermocompression bonding, followed by curing to form the electrically insulating layer. Further, the conductor layer 2 is formed thereon in accordance with the above-mentioned method. Further multilayer formation may be performed by repeating the foregoing procedure. Thus, a desired multilayer circuit board may be obtained.

The thus obtained composite body (composite material cured article and multilayer circuit board as an example thereof) has the electrically insulating layer obtained by curing the curable resin composition or the curable composite material of the present invention, and the electrically insulating layer has low linear expansion and is excellent in electrical characteristics, heat resistance, and wire embedding flatness. Accordingly, the composite body of the present invention may be suitably used in various applications, such as an electrical and electronic part.

In addition, when the electrically insulating layer of the composite body of the present invention is formed of the laminated film or the prepreg formed of the laminated film and the fiber base material, the electrically insulating layer can have high peel strength in addition to having low linear expansion and being excellent in electrical characteristics, heat resistance, and wire embedding flatness. In addition, in this case, in forming the conductor layer on the electrically insulating layer and patterning the formed conductor layer to form fine wiring, it is possible to satisfactorily perform the patterning of the conductor layer.

An electrical and electronic part of the present invention uses the cured article of the present invention. The electrical and electronic part may be suitably used as a part for any of various electrical and electronic devices required to have reliability under an environment where heat resistance and water resistance are required and to have transmission reliability of a high frequency signal, such as a mobile phone, a PHS, a notebook computer, a personal digital assistant (PDA), a portable video phone, a personal computer, a supercomputer, a server, a router, a liquid crystal projector, an engineering workstation (EWS), a pager, a word processor, a television, a viewfinder-type or monitor direct-view-type video tape recorder, an electronic organizer, an electronic desk calculator, a car navigation system, a POS terminal, and a device having a touch panel. In particular, the electrical and electronic part may be suitably used as a circuit board for the electrical and electronic devices by virtue of the thermal stability of the excellent dielectric characteristics of the cured article of the present invention, and its dimensional stability and moldability compatible with fine-pattern circuit formation. Specific examples of the circuit board include a single-sided, double-sided, or multilayer printed board, a flexible substrate, and a build-up substrate. The multilayer circuit board using the metal plating as the conductor layer is also included as a preferred example.

### EXAMPLES

Now, the present invention is described by way of Examples, but the present invention is not limited thereto. It should be noted that the term “part (s)” in each example refers to “part (s) by weight”. In addition, measurement results in Examples were obtained by performing sample preparation and measurement by methods described below.

(1) Molecular Weight and Molecular Weight Distribution (Mw/Mn) of Aromatic Polyester

A molecular weight and a molecular weight distribution were measured using GPC (manufactured by Tosoh Corporation, HLC-8120GPC) with tetrahydrofuran (THF) as a solvent at a flow rate of 1.0 ml/min and a column temperature of 40° C. The molecular weight was measured as a molecular weight in terms of polystyrene using a calibration curve prepared with monodispersed polystyrene.

(2) Glass Transition Temperature (Tg) and Softening Temperature

A curable resin composition solution was uniformly applied onto a polyethylene terephthalate film whose support had been subjected to easy-peel treatment (PET film; thickness: 38 μm) with a die coater so that a resin composition layer after drying had a thickness of 50 μm, and the applied solution was dried using an inert oven under a stream of nitrogen at 90° C. for 10 min (amount of residual solvent in resin composition layer: about 1.7 mass %). The resultant adhesive film was heated at 190° C. for 90 min to be thermally cured, and the support was peeled to provide a film-shaped cured article. The resultant cured article film was cut into a size applicable to measurement with a thermomechanical analyzer (TMA measuring apparatus), and subjected to heating treatment under a stream of nitrogen in an inert oven at 200° C. for 30 min to remove the residual solvent. The cured article film was allowed to cool to room temperature, and then set in the TMA measuring apparatus. Measurement was performed by scanning from 30° C. to 320° C. under a stream of nitrogen at a rate of temperature increase of 10° C./min, and an inflection point at which a linear expansion coefficient changed was determined as Tg by a tangent method. Further, an average linear expansion coefficient (CTE) was calculated from the dimensional change of the test piece at from 0° C. to 40° C.

The Tg of the cured article film obtained by heating press molding was measured using a dynamic viscoelasticity measuring apparatus at a rate of temperature increase of 3° C./min and determined from the peak of a loss elastic modulus.

(4) Tensile Strength and Elongation Rate

The tensile strength and the elongation rate of the cured article film were measured using a tensile tester. The elongation rate was measured from a chart of a tensile test.

(5) Dielectric Constant and Dielectric Loss Tangent, and Change Ratios Thereof

In conformity with the JIS C2565 standard, a cavity resonator method dielectric constant measuring apparatus manufactured by AET, Inc. was used to measure a dielectric constant and a dielectric loss tangent at 18.0 GHz for each of a cured article sheet after being absolutely dried under vacuum at 80° C., and a cured article sheet after being left to stand in a constant temperature and humidity chamber at 85° C. and a relative humidity of 85% for 3 weeks after the determination of its constant mass in a desiccator after the absolute drying.

In addition, the cured article film was measured for its dielectric constant and dielectric loss tangent after being left to stand in an oven under an air atmosphere at 200° C. for 1 hr, and change ratios of the dielectric constant and the dielectric loss tangent between before and after the standing were measured.

(6) Copper Foil Peel Strength

A test piece having a width of 20 mm and a length of 100 mm cut out of a laminated body, and a parallel cut having a width of 10 mm was formed in its copper foil surface. After that, the copper foil was continuously peeled in a direction of 180° with respect to the surface at a rate of 50 mm/min, and a stress at this time was measured with a tensile testing machine. The minimum value of the stress is shown (in conformity with JIS C 6481).

(7) Moldability

An uncured film of a curable resin composition was laminated on a copper-lined laminated plate subjected to blackening treatment, and vacuum lamination was performed using a vacuum laminator at a temperature of 110° C. and a press pressure of 0.1 MPa. Evaluation was performed on the basis of the bonded state of the blackening-treated copper foil and the film. The evaluation was performed by: marking the case where the bonded state of the blackening-treated copper foil and the film was satisfactory with Symbol “∘”; marking the case where the blackening-treated copper foil and the film were in a bonded state of being easily peelable with Symbol “x”; and marking the case where partial peeling or warping occurred with Symbol “Δ”.

(8) Wire Embedding Flatness

A film molded body was laminated on each of both surfaces of an inner layer circuit board (IPC MULTI-PURPOSE TESTBOARD No. IPC-B-25, conductor thickness: 30 μm, 0.8 mm thick) so that its resin layer-side surface was brought into contact therewith. Specifically, primary press was performed by thermocompression bonding at a temperature of 110° C., a pressure of 0.1 MPa for 90 sec with a vacuum laminator including upper and lower heat-resistant rubber press plates under a reduced pressure of 200 Pa. Further thermocompression bonding was performed using a hydraulic press apparatus including upper and lower metal press plates at a compression bonding temperature of 110° C. and 1 MPa for 90 sec. Thus, a laminated body was obtained. Then, a supporting film was peeled from the laminated body, and the resultant was cured at 180° C. for 60 min. After the curing, a step difference between a portion having a conductor and a portion having no conductor in a comb-like pattern region having a conductor width of 165 μm and a conductor interval of 165 μm was measured with a stylus type step difference thickness meter (P-10 manufactured by Tencor Instruments), and wire embedding flatness was evaluated by the following criteria.

∘: The step difference is less than 2 μm.

Δ: The step difference is 2 μm or more and less than 3 μm.

x: The step difference is 3 μm or more.

(10) Liquid Crystal Phase Transition Temperature

The liquid crystal phase transition temperature of an aromatic polyester was measured by heating sample resin powder having a particle diameter of 250 μm or less placed on a heating stage under polarized light at a rate of 25° C./min, and observing optical anisotropy in a molten state with the naked eye.

(11) Sum of Hydroxy Group Equivalent and Carboxyl Group Equivalent

The sum of the hydroxy group equivalent and the carboxyl group equivalent of an aromatic polyester was determined as described below. 1.5 g to 2.0 g of a sample of the aromatic polyester was weighed in a round-bottom flask to the order of 1 mg. 25 mL of a 0.5 mol/L potassium hydroxide ethanol solution was added using a volumetric pipette. An air cooler was mounted onto the flask, and the contents were subjected to a reaction by being gently heated at 80° C. for 2 hr in an oil bath or on a heating plate while being occasionally shaken. During the heating, the heating temperature was adjusted so as to prevent the reflux flow of refluxing ethanol from reaching an upper end of the air cooler. Immediately after the completion of the reaction, the round-bottom flask was removed from a heating source, and before the contents were solidified into an agar-like form, a small amount of water was sprayed from above the air cooler to wash its inner wall. After that, the air cooler was removed. A decomposition product obtained by decomposition was used for liquid chromatography to quantify (a) the aromatic oxycarboxylic acid, (b) the polyfunctional aromatic compound, and (c) the monofunctional aromatic compound, and the sum of a hydroxy group equivalent and a carboxyl group equivalent at the ends of the aromatic polyester was calculated on the basis of the quantified values of the components (a) to (c).

(12) Residual Acetic Acid and Residual Acetic Anhydride (Acetic Acid Total Amount)

The sum of residual acetic acid and residual acetic anhydride of an aromatic polyester was measured by dissolving the aromatic polyester in cyclopentanone, and performing gas chromatography with 1-methylnaphthalene as an internal standard substance.

(13) Solution Viscosity

A solution viscosity was measured at 25° C. using an E-type viscometer.

### EXAMPLE 1

493.3 g (3.5 mol) of p-hydroxybenzoic acid, 672.1 g (3.5 mol) of 6-hydroxy-2-naphthoic acid, 167.8 g (1.0 mol) of isophthalic acid, 294.2 g (2.0 mol) of 1-naphthol, 2.2 g (0.0075 mol) of antimony trioxide, and 1,894.4 g (18.0 mol) of acetic anhydride were loaded into a polymerization tank with a comb-like stirring blade, and were heated while being stirred under a nitrogen gas atmosphere, so as to be subjected to a reaction at 220° C. for 1 hr, at 240° C. for 1 hr, and at 280° C. for 1 hr. Then, the degree of pressure reduction was gradually increased, and polymerization was further performed under a reduced pressure of 2.0 torr at 300° C. for 1 hr. During this procedure, acetic acid generated as a by-product was continuously evaporated out of the system. After that, the system was gradually cooled, and a polymer obtained at 180° C. was taken out of the system.

The resultant polymer was dissolved in 7,600 ml of γ-butyrolactone, and then the solution was charged into 30 L of methanol under vigorous stirring to reprecipitate a product. The resultant resin precipitate was filtered and dried to provide an aromatic polyester. Each structural unit (raw material name) and its molar ratio are shown in Table 1. The molar ratio is a value calculated from the amount of a raw material. The aromatic polyester is hereinafter abbreviated as CLCP-A. This polymer showed optical anisotropy at 150° C. or more.

### EXAMPLES 2 TO 6

Aromatic polyesters (CLCP-B to CLCP-F) were obtained in the same manner as in Example 1 except that the kinds and the composition of (a) the aromatic oxycarboxylic acid, (b) the aromatic polyvalent carboxylic acid, and (c) the aromatic monohydroxy compound were changed as shown in Table 1 below. The results are shown in Table 1.

TABLE 1

| Example | 1 | 2 | 3 | 4 | 5 | 6 |
|---|---|---|---|---|---|---|
| Aromatic polyester CLCP | A | B | C | D | E | F |
| 2-Hydroxy-6-naphthoic | 35 | 50 | 35 | 35 | 40 | 15 |
| acid | | | | | | |
| 4-Hydroxybenzoic acid | 35 | 20 | 35 | 25 | | 40 |
| 3-Hydroxybenzoic acid | | | | 10 | | |
| Isophthalic acid | 10 | 10 | 10 | | 10 | 15 |
| Terephthalic acid | | | | 10 | | |
| 4,4′-Biphenyldicarboxylic | | | | | 10 | |
| acid | | | | | | |
| 1-Naphthol | 20 | 20 | | | 40 | |
| 2-Naphthol | | | 20 | | | 30 |
| 4-Phenylphenol | | | | 20 | | |
| Mn (—) | 1,420 | 1,320 | 1,210 | 1,280 | 857 | 983 |
| Mw (—) | 2,250 | 2,160 | 2,270 | 2,170 | 1,460 | 1,610 |
| Mw/Mn (—) | 1.58 | 1.64 | 1.88 | 1.70 | 1.70 | 1.64 |
| Liquid crystal phase | 150 | 180 | 210 | 180 | 150 | 150 |
| transition temperature | | | | | | |
| (° C.) | | | | | | |
| COOH equivalent (g/eq.) | 10,100 | 7,800 | 8,700 | 10,600 | 5,600 | 6,380 |
| Residual acetic acid (wt %) | 0.00 | 0.01 | 0.02 | 0.00 | 0.01 | 0.01 |

### EXAMPLE 7

g of CLCP-A obtained in Example 1, 30 g of a naphthol-aralkyl-type epoxy resin ESN-475 manufactured by Nippon Steel & Sumikin Chemical Co., Ltd. as an epoxy resin, and 100 g of γ-butyrolactone were heated to 80° C., and were stirred and mixed. Then, 0.3 g of 2-methyl-4-ethylimidazole (2E4MZ, manufactured by Tokyo Chemical Industry Co., Ltd.) was added as a reaction catalyst.

After that, the mixture was heated to a reaction temperature of 140° C. and kept at the temperature for 1 hr to be subjected to a reaction. It should be noted that the ester compound in the reaction liquid was stirred and mixed while partially generating insoluble matter at the initial stage of the reaction because of insufficient solubility in the reaction solvent and the epoxy resin, but homogeneously dissolved over time.

After the completion of the reaction, 3.0 g of the curable resin composition solution was weighed on a mold, and the composition solution was heated under vacuum to 160° C. using a vacuum dryer to remove air bubbles and residual volatile contents (including water). Thus, an intermediate reaction product of the curable resin composition was obtained.

The mold having placed thereon the intermediate reaction product was assembled, and then vacuum-pressure press was performed under the conditions of 180° C. and 3 MPa for 90 min to cause thermal curing. The resultant cured article sheet having a thickness of 0.2 mm was measured for various characteristics including a dielectric constant and a dielectric loss tangent. In addition, change ratios of the dielectric constant and the dielectric loss tangent after a wet heat test were measured. The results obtained by the measurement are shown in Table 2.

### EXAMPLES 8 TO 12 AND COMPARATIVE EXAMPLE 1

Molding, test piece production, and measurement of various characteristics were performed by the same methods as those of Example 7 except that the blend was changed as described in Table 2. The results obtained are shown in Table 2. In Comparative Example 1, the dielectric constant, the dielectric loss tangent, and the dielectric loss tangent change ratio could not be measured because the dielectric loss of the material was large and exceeded the measurable range of the measuring apparatus. In the table, * represents unmeasurable.

Descriptions of symbols in the following tables.

ESN-475: Naphthol-aralkyl-type epoxy resin (manufactured by Nippon Steel & Sumikin Chemical Co., Ltd.)
(CN value (which is an area percentage of aromatic carbon atoms in the resonance line area of all carbon atoms detected in ¹³C-NMR): 76.5%)
ESN-165S: Naphthalenephenol-novolac-type epoxy resin (manufactured by Nippon Steel & Sumikin Chemical Co., Ltd.) (CN value: 76.5%)
ESN-375: β-Naphthol-aralkyl-type epoxy resin (manufactured by Nippon Steel & Sumikin Chemical Co., Ltd.)
(CN value: 65.0%)
XD-1000: Dicyclopentadiene-type epoxy resin (manufactured by Nippon Kayaku Co., Ltd.)
(CN value: 38.3%)
YDCN-700-3: Phenol novolac-type epoxy resin (manufactured by Nippon Steel & Sumikin Chemical Co., Ltd.)
(CN value: 54.5%)
TPP: Triphenyl phosphine

TABLE 2

| | Example | | | | | | Comparative |
|---|---|---|---|---|---|---|---|
| | 7 | 8 | 9 | 10 | 11 | 12 | Example 1 |
| Aromatic polyester CLCP | A | B | C | D | E | F | |
| | 65 | 65 | 65 | 65 | 65 | 65 | |
| MEH-7851-S | | | | | | | 65 |
| ESN-475 | 35 | 35 | | | | | 35 |
| ESN-165S | | | 35 | | | | |
| ESN-375 | | | | 35 | | | |
| XD-1000 | | | | | 35 | | |
| YDCN-700-3 | | | | | | 35 | |
| 2E4MZ | 0.3 | 0.3 | 0.3 | 0.3 | 0.3 | | 0.3 |
| TPP | | | | | | 0.5 | |
| Solution viscosity | 207 | 256 | 311 | 390 | 637 | 189 | 357 |
| (mPa · s) | | | | | | | |
| Linear expansion | 51.9 | 57.6 | 53.4 | 56.9 | 58.6 | 54.8 | 59.3 |
| coefficient | | | | | | | |
| (ppm/° C.) | | | | | | | |
| Glass transition | 187.6 | 190.6 | 181.7 | 178.9 | 180.9 | 184.2 | 175.3 |
| temperature | | | | | | | |
| (° C.) | | | | | | | |
| Dielectric | 2.98 | 3.02 | 3.01 | 2.97 | 2.87 | 2.92 | 3.07 |
| constant | | | | | | | |
| Dielectric loss | 0.0033 | 0.0037 | 0.0041 | 0.0042 | 0.0057 | 0.0055 | 0.0171 |
| tangent | | | | | | | |
| Dielectric | 3.01 | 2.99 | 3.03 | 2.95 | 2.84 | 2.95 | * |
| constant after 3 | | | | | | | |
| weeks at 85° C. | | | | | | | |
| Dielectric loss | 0.0044 | 0.0051 | 0.0058 | 0.0063 | 0.0082 | 0.0078 | * |
| tangent after 3 | | | | | | | |
| weeks at 85° C. | | | | | | | |
| Dielectric loss | 25.0 | 27.5 | 29.3 | 33.3 | 30.5 | 29.5 | * |
| tangent change | | | | | | | |
| ratio (%) | | | | | | | |
| Moldability | ∘ | ∘ | ∘ | ∘ | ∘ | ∘ | Δ |
| Wire embedding | ∘ | ∘ | ∘ | ∘ | ∘ | ∘ | Δ |
| flatness | | | | | | | |

### EXAMPLES 13 AND 14

### Preparation of Curable Resin Composition

60 g of CLCP-A or CLCP-B obtained in Example 1 or 2, 30 g of a naphthol-aralkyl-type epoxy resin ESN-475 manufactured by Nippon Steel & Sumikin Chemical Co., Ltd. as an epoxy resin, 10 g (in terms of solid content) of YL7553BH30 (weight-average molecular weight: 37,000, manufactured by Mitsubishi Chemical Corporation, YL7553BH30, solution containing MEK and cyclohexanone at 1:1 and having a non-volatile content of 30 mass %) as a phenoxy resin, 200 g of spherical silica (trade name: SC2500-SXJ, manufactured by Admatechs Company Limited) as the filler (E), and 100 g of γ-butyrolactone as a solvent were mixed, and homogeneously dispersed with a high-speed rotation mixer to produce a varnish of a thermosetting resin composition.

0.3 g of 2E4MZ was further mixed as a reaction catalyst into the varnish, and the mixture was stirred with a planetary stirrer for 5 min to provide a curable resin composition. It should be noted that the solution viscosity was measured at 25° C. with an E-type viscometer.

(Production of Film Molded Body)

Next, the varnish of the curable resin composition obtained in the foregoing was applied onto a polyethylene terephthalate film having a size of 300 mm long by 300 mm wide, a thickness of 38 μm, and a surface average roughness Ra of 0.08 μm (support: Lumirror (trademark) T60 manufactured by Toray Industries, Inc.) using a die coater, and was then dried under a nitrogen atmosphere at 80° C. for 10 min to provide a film molded body of the resin composition having a thickness of 48 μm on the support. Then, the resultant film molded body was used to measure wire embedding flatness in accordance with the above-mentioned method. The results are shown in Table 3.

(Production of Film-Shaped Cured Article)

Next, a small piece cut out of the resultant film molded body of the curable resin composition was laminated on a copper foil having a thickness of 10 μm while being in a state of having the support by thermocompression bonding at a temperature of 110° C. and a pressure of 0.1 MPa for 60 sec using a vacuum laminator including upper and lower heat-resistant rubber press plates under a reduced pressure of 200 Pa so that the curable resin composition was arranged inside. The support was peeled off, and then curing was performed by heating in air at 180° C. for 120 min. After the curing, the cured resin with a copper foil was cut out, and the copper foil was dissolved with a 1 mol/L ammonium persulfate aqueous solution to provide a film-shaped cured article. The resultant film-shaped cured article was used to measure a specific dielectric constant, a dielectric loss tangent, a linear expansion coefficient, a glass transition temperature, and change ratios of the dielectric constant and the dielectric loss tangent in accordance with the above-mentioned methods. The results obtained by the measurement are shown in Table 3.

### COMPARATIVE EXAMPLE 2

A resin composition, a film molded body, and a film-shaped cured article were obtained in the same manner as in Example 13 except that a phenol resin MEH-7851-S was used as a curing agent in place of CLCP-A obtained in Example 1 to achieve a blend shown in Table 3. The results are shown in Table 3.

TABLE 3

| | Example | | Comparative |
|---|---|---|---|
| | 13 | 14 | Example 2 |
| CLCP-A | 60 | | |
| CLCP-B | | 60 | |
| MEH-7851-S | | | 60 |
| ESN-475 | 30 | 30 | 30 |
| YL7553BH30 | 10 | 10 | 10 |
| 2E4MZ | 0.3 | 0.3 | 0.3 |
| SC2500-SXJ (g) | 200 | 200 | 200 |
| γ-Butyrolactone | 100 | 100 | 100 |
| Solution viscosity | 5,260 | 6,430 | 7,210 |
| (mPa · s) | | | |
| Tensile strength (MPa) | 45.8 | 40.3 | 36.9 |
| Tensile breaking | 6.9 | 6.4 | 7.1 |
| elongation (%) | | | |
| Linear expansion coefficient | 37.6 | 39.8 | 47.6 |
| (ppm/° C.) | | | |
| Glass transition temperature | 202.7 | 200.5 | 186.2 |
| (° C.) | | | |
| Dielectric constant | 3.072 | 3.101 | 3.513 |
| Dielectric loss tangent | 0.0012 | 0.0018 | 0.0092 |
| Dielectric constant after | 3.057 | 3.091 | * |
| 3 weeks at 85° C. | | | |
| Dielectric loss tangent | 0.0021 | 0.0035 | * |
| after 3 weeks at 85° C. | | | |
| Dielectric loss tangent | 42. 9 | 48.6 | * |
| change ratio (%) | | | |
| Copper foil peel | 0.87 | 0.81 | 0.63 |
| strength (N/mm) | | | |
| After wet heat test | 0.77 | 0.68 | 0.42 |
| (after 85° C. × | | | |
| 85RH × 1 week) | | | |
| Moldability | ∘ | ∘ | Δ |
| Wire embedding flatness | ∘ | ∘ | Δ |

### EXAMPLE 21

493.3 g (3.5 mol) of p-hydroxybenzoic acid, 672.1 g (3.5 mol) of 6-hydroxy-2-naphthoic acid, 111.2 g (1.0 mol) of resorcinol, 245.5 g (2.0 mol) of benzoic acid, 2.2 g (0.0075 mol) of antimony trioxide, and 1,894.4 g (18.0 mol) of acetic anhydride were loaded into a polymerization tank with a comb-like stirring blade, and were heated while being stirred under a nitrogen gas atmosphere, so as to be subjected to a reaction at 220° C. for 1 hr, at 240° C. for 1 hr, and at 280° C. for 1 hr. Then, the degree of pressure reduction was gradually increased, and polymerization was further performed under a reduced pressure of 2.0 torr at 300° C. for 1 hr. During this procedure, acetic acid generated as a by-product was continuously evaporated out of the system. After that, the system was gradually cooled, and a polymer obtained at 180° C. was taken out of the system.

The resultant polymer was dissolved in 7,600 ml of γ-butyrolactone, and then the solution was charged into 30 L of methanol under vigorous stirring to reprecipitate a product. The resultant resin precipitate was filtered and dried to provide a wholly aromatic polyester formed of repeating units described below. The molar ratio of each structural unit was calculated from the amount of a raw material. This liquid crystal polyester is hereinafter abbreviated as CLCP-2A. This polymer showed optical anisotropy at 150° C. or more.

### EXAMPLES 22 TO 26

Liquid crystal polyesters (CLCP-2B to CLCP-2F) were obtained in the same manner as in Example 21 except that the kinds and the composition of (a) the aromatic oxycarboxylic acid, (b) the aromatic polyhydric hydroxy compound, and (c) the aromatic monocarboxylic acid were changed as shown in Table 4 below. The results are shown in Table 4.

TABLE 4

| Example | 21 | 22 | 23 | 24 | 25 | 26 |
|---|---|---|---|---|---|---|
| Aromatic polyester CLCP | 2A | 2B | 2C | 2D | 2E | 2F |
| 2-Hydroxy-6-naphthoic acid | 35 | 50 | 35 | 35 | 40 | 15 |
| 4-Hydroxybenzoic acid | 35 | 20 | 35 | 25 | | 40 |
| 3-Hydroxybenzoic acid | | | | 10 | | |
| Resorcinol | 10 | 10 | 10 | | 10 | 15 |
| Hydroquinone | | | | 10 | | |
| 4,4′-Dihydroxybiphenyl | | | | | 10 | |
| Benzoic acid | 20 | 20 | | | 40 | |
| 1-Naphthoic acid | | | 20 | | | 30 |
| 4-Phenylbenzoic acid | | | | 20 | | |
| Mn (—) | 1,420 | 1,320 | 1,210 | 1,280 | 857 | 983 |
| Mw (—) | 2,250 | 2,160 | 2,270 | 2,170 | 1,460 | 1,610 |
| Mw/Mn (—) | 1.58 | 1.64 | 1.88 | 1.70 | 1.70 | 1.64 |
| Liquid crystal phase | 150 | 180 | 210 | 180 | 150 | 150 |
| transition temperature | | | | | | |
| (° C.) | | | | | | |
| COOH equivalent (g/eq.) | 10,100 | 7,800 | 8,700 | 10,600 | 5,600 | 6,380 |
| Residual acetic acid | 0.00 | 0.01 | 0.02 | 0.00 | 0.01 | 0.01 |
| (wt %) | | | | | | |
| Total | 100 | 100 | 100 | 100 | 100 | 100 |

### EXAMPLE 27

65 g of CLCP-2A obtained in Example 21, 35 g of a naphthol-aralkyl-type epoxy resin ESN-475 manufactured by Nippon Steel & Sumikin Chemical Co., Ltd. as an epoxy resin, and 100 g of cyclohexanone were heated to 80° C., and were stirred and mixed. Then, 0.3 g of 2-methyl-4-ethylimidazole (2E4MZ, manufactured by Tokyo Chemical Industry Co., Ltd.) was added as a reaction catalyst.

After that, the mixture was heated to a reaction temperature of 140° C. and kept at the temperature for 1 hr to be subjected to a reaction. It should be noted that the ester compound in the reaction liquid was stirred and mixed while partially generating insoluble matter at the initial stage of the reaction because of insufficient solubility in the reaction solvent and the epoxy resin, but homogeneously dissolved over time.

After the completion of the reaction, 3.0 g of the curable resin composition solution was weighed on a mold, and the composition solution was heated under vacuum to 160° C. using a vacuum dryer to remove the solvent. Thus, an intermediate reaction product of the curable resin composition was obtained.

The mold having placed thereon the intermediate reaction product was assembled, and then vacuum-pressure press was performed under the conditions of 180° C. and 3 MPa for 90 min to cause thermal curing. The resultant cured article sheet having a thickness of 0.2 mm was measured for various characteristics including a dielectric constant and a dielectric loss tangent. In addition, change ratios of the dielectric constant and the dielectric loss tangent after a wet heat test were measured. The results obtained by the measurement are shown in Table 5.

### EXAMPLES 28 TO 32 AND COMPARATIVE EXAMPLE 21

Molding, test piece production, and measurement of various characteristics were performed by the same methods as those of Example 27 except that the blend was changed as described in Table 5. The results obtained are shown in Table 5.

TABLE 5

| | | | | | | | Comparative |
|---|---|---|---|---|---|---|---|
| | Example | | | | | | Example |
| | 27 | 28 | 29 | 30 | 31 | 32 | 21 |
| Polyester CLCP | 2A | 2B | 2C | 2D | 2E | 2F | |
| | 65 | 65 | 65 | 65 | 65 | 65 | |
| MEH-7851-S | | | | | | | 65 |
| ESN-475 | 35 | 35 | | | | | 35 |
| ESN-165S | | | 35 | | | | |
| ESN-375 | | | | 35 | | | |
| XD-1000 | | | | | 35 | | |
| YDCN-700-3 | | | | | | 35 | |
| 2E4MZ | 0.3 | 0.3 | 0.3 | 0.3 | 0.3 | | 0.3 |
| TPP | | | | | | 0.5 | |
| Solution viscosity | 157 | 236 | 207 | 288 | 578 | 169 | 367 |
| (mPa · s) | | | | | | | |
| Linear expansion | 52.6 | 54.2 | 55.6 | 51.3 | 59.6 | 54.3 | 61.3 |
| coefficient | | | | | | | |
| (ppm/° C.) | | | | | | | |
| Glass transition | 176.5 | 181.5 | 178.2 | 180.6 | 170.5 | 186.3 | 171.3 |
| temperature | | | | | | | |
| (° C.) | | | | | | | |
| Dielectric | 2.98 | 3.01 | 2.94 | 3.08 | 2.84 | 2.91 | 3.07 |
| constant | | | | | | | |
| Dielectric loss | 0.0035 | 0.0031 | 0.0037 | 0.0044 | 0.0067 | 0.0052 | 0.0171 |
| tangent | | | | | | | |
| Dielectric | 3.01 | 3.01 | 2.97 | 2.94 | 2.86 | 2.97 | * |
| constant after 3 | | | | | | | |
| weeks at 85° C. | | | | | | | |
| Dielectric loss | 0.0046 | 0.0049 | 0.0056 | 0.0062 | 0.0088 | 0.0081 | * |
| tangent after 3 | | | | | | | |
| weeks at 85° C. | | | | | | | |
| Dielectric loss | 31.4 | 58.1 | 56.8 | 40.9 | 31.3 | 36.5 | * |
| tangent change | | | | | | | |
| ratio (%) | | | | | | | |
| Moldability | ∘ | ∘ | ∘ | ∘ | ∘ | ∘ | Δ |
| Wire embedding | ∘ | ∘ | ∘ | ∘ | ∘ | ∘ | Δ |
| flatness | | | | | | | |

### EXAMPLE 33

### Preparation of Curable Resin Composition

60 g of CLCP-2A obtained in Example 21, 30 g of a naphthol-aralkyl-type epoxy resin ESN-475 manufactured by Nippon Steel & Sumikin Chemical Co., Ltd. as an epoxy resin, 10 g (in terms of solid content) of YL7553BH30 (weight-average molecular weight: 37,000, manufactured by Mitsubishi Chemical Corporation, a solution containing MEK and cyclohexanone at 1:1 and having a non-volatile content of 30 mass %) as a phenoxy resin, 200 g of spherical silica (trade name: “SC2500-SXJ”, manufactured by Admatechs Company Limited, aminosilane-type silane coupling agent-treated product, volume-average particle diameter: 0.5 μm) as the filler (E), and 100 g of γ-butyrolactone as a solvent were mixed, and homogeneously dispersed with a high-speed rotation mixer to produce a varnish of a thermosetting resin composition.

0.3 g of 2-methyl-4-ethylimidazole (2E4MZ, manufactured by Tokyo Chemical Industry Co., Ltd.) was further mixed as a reaction catalyst into the varnish, and the mixture was stirred with a planetary stirrer for 5 min to provide a curable resin composition. It should be noted that the solution viscosity was measured at 25° C. with an E-type viscometer.

(Production of Film Molded Body)

Next, the varnish of the curable resin composition obtained in the foregoing was applied onto a polyethylene terephthalate film having a size of 300 mm long by 300 mm wide, a thickness of 38 μm, and a surface average roughness Ra of 0.08 μm (support: Lumirror (trademark) T60 manufactured by Toray Industries, Inc.) using a die coater, and was then dried under a nitrogen atmosphere at 80° C. for 10 min to provide a film molded body of the resin composition having a thickness of 48 μm on the support. Then, the resultant film molded body was used to measure wire embedding flatness in accordance with the above-mentioned method. The results are shown in Table 6.

(Production of Film-Shaped Cured Article)

Next, a small piece cut out of the resultant film molded body of the curable resin composition was laminated on a copper foil having a thickness of 10 μm while being a state of having the support by thermocompression bonding at a temperature of 110° C. and a pressure of 0.1 MPa for 60 sec using a vacuum laminator including upper and lower heat-resistant rubber press plates under a reduced pressure of 200 Pa so that the curable resin composition was arranged inside. The support was peeled off, and then curing was performed by heating in air at 180° C. for 120 min. After the curing, the cured resin with a copper foil was cut out, and the copper foil was dissolved with a 1 mol/L ammonium persulfate aqueous solution to provide a film-shaped cured article. The resultant film-shaped cured article was used to measure a specific dielectric constant, a dielectric loss tangent, a linear expansion coefficient, a glass transition temperature, and change ratios of the dielectric constant and the dielectric loss tangent in accordance with the above-mentioned methods. The results obtained by the measurement are shown in Table 6.

### EXAMPLE 34 AND COMPARATIVE EXAMPLE 22

Resin compositions, film molded bodies, and film-shaped cured articles were obtained in the same manner as in Example 33 except that CLCP-2B or a phenol resin MEH-7851-S as a curing agent was used in place of CLCP-2A obtained in Example 21 to achieve a blend shown in Table 6. The results are shown in Table 6.

TABLE 6

| | Example | | Comparative |
|---|---|---|---|
| | 33 | 34 | Example 22 |
| CLCP-2A | 60 | | |
| CLCP-2B | | 60 | |
| MEH-7851-S | | | 60 |
| ESN-475 | 30 | 30 | 30 |
| YL7553BH30 | 10 | 10 | 10 |
| 2E4MZ | 0.3 | 0.3 | 0.3 |
| SC2500-SXJ (g) | 200 | 200 | 200 |
| γ-Butyrolactone | 100 | 100 | 100 |
| Solution viscosity | 5,260 | 6,430 | 7,210 |
| (mPa · s) | | | |
| (25° C., E-type viscometer) | | | |
| Tensile strength (MPa) | 45.8 | 40.3 | 36.9 |
| Tensile breaking | 6.9 | 6.4 | 7.1 |
| elongation (%) | | | |
| Linear expansion coefficient | 37.6 | 39.8 | 47.6 |
| (ppm/° C.) | | | |
| Glass transition temperature | 202.7 | 200.5 | 186.2 |
| (° C.) | | | |
| Dielectric constant | 3.072 | 3.101 | 3.513 |
| Dielectric loss tangent | 0.0012 | 0.0018 | 0.0092 |
| Dielectric constant after | 3.057 | 3.091 | * |
| 85° C. × 85RH × 3 weeks | | | |
| Dielectric loss tangent after | 0.0021 | 0.0035 | * |
| 85° C. × 85RH × 3 weeks | | | |
| Dielectric loss tangent | 42.9 | 48.6 | * |
| change ratio (%) | | | |
| Copper foil peel | 0.87 | 0.81 | 0.63 |
| strength (N/mm) | | | |
| After wet heat test | 0.77 | 0.68 | 0.42 |
| (after 85° C. × | | | |
| 85RH × 1 week) | | | |
| Moldability | ∘ | ∘ | Δ |
| Wire embedding flatness | ∘ | ∘ | Δ |

The curable resin composition containing an aromatic polyester or the cured article obtained by curing the curable resin composition of the present invention is suitably used as a dielectric material, an insulating material, or a heat-resistant material in an advanced material field, such as an electrical industry or a space and aircraft industry, and may be utilized, for example, in a material for an electrical and electronic part, in particular, as a circuit board material for a single-sided, double-sided, or multilayer printed board, a flexible printed board, a build-up substrate, or the like.

1. A curable resin composition, comprising:
an aromatic polyester as a component (A); and
an epoxy resin having two or more epoxy groups per molecule as a component (D),
wherein the component (A) comprises an aromatic polyester obtained by condensing:
(a) an aromatic oxycarboxylic acid;
(b) one of an aromatic polyvalent carboxylic acid and an aromatic polyhydric hydroxy compound; and
(c) one of an aromatic monohydroxy compound and an aromatic monocarboxylic acid.

2. A curable resin composition according to claim 1, wherein the aromatic oxycarboxylic acid (a) comprises at least one kind of compound selected from the following group (4):

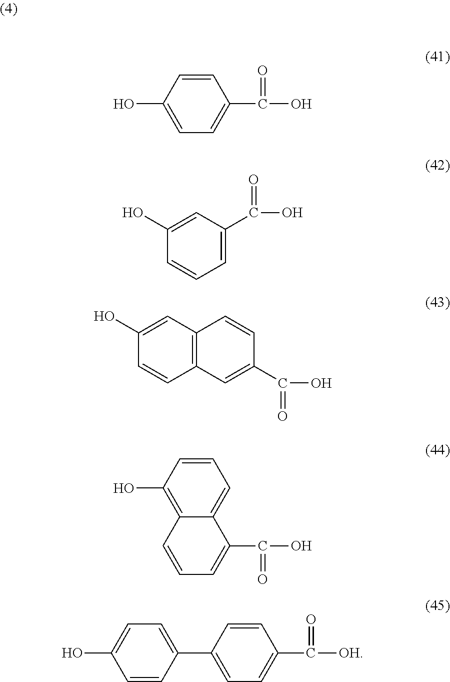

3. A curable resin composition according to claim 1, wherein the one of an aromatic polyvalent carboxylic acid and an aromatic polyhydric hydroxy compound (b) comprises at least one kind of compound selected from one of the following group (5) and the following group (6):

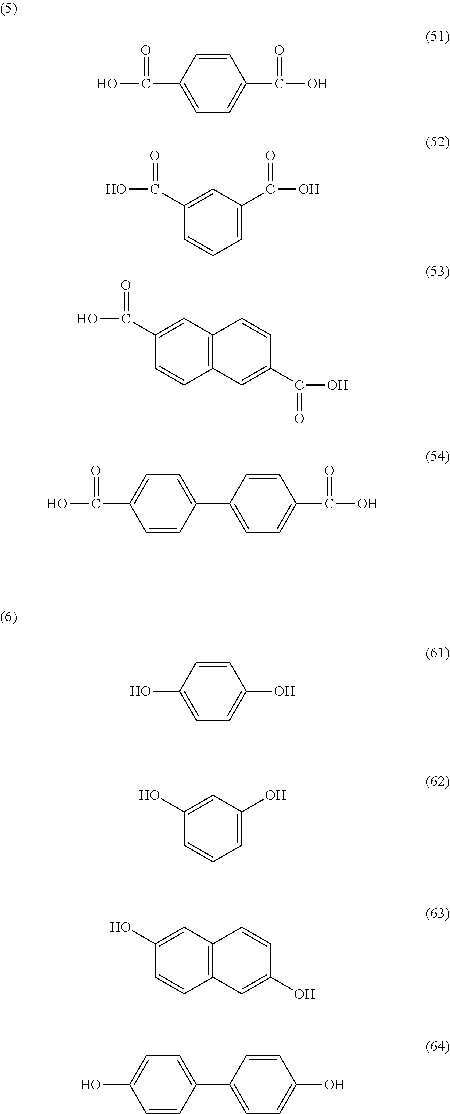

4. A curable resin composition according to claim 1, wherein the one of an aromatic monohydroxy compound and an aromatic monocarboxylic acid (c) comprises at least one kind of compound selected from one of the following group (7) and the following group (8): 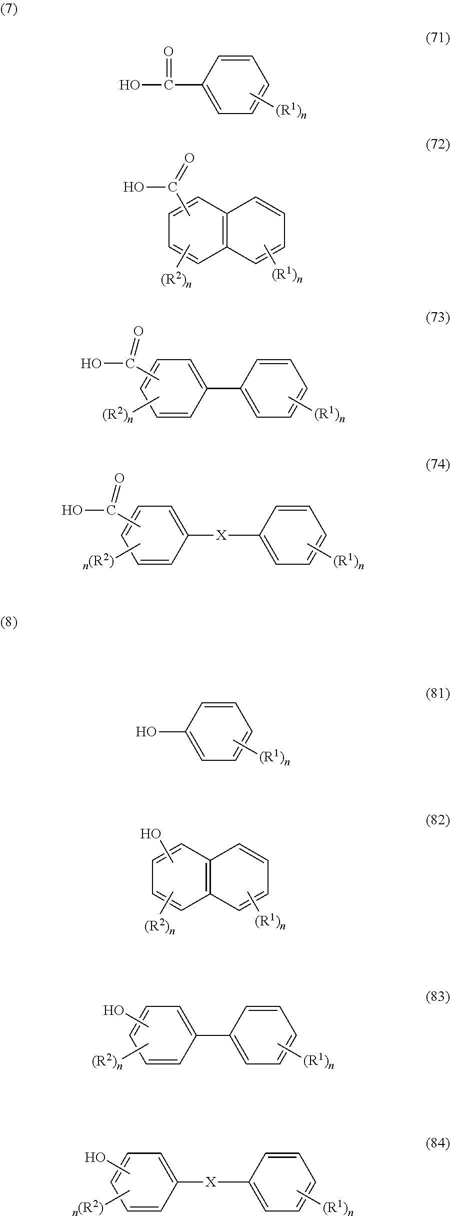
where R¹ and R² each independently represent an alkyl group having 1 to 10 carbon atoms, an alkoxy group having 1 to 10 carbon atoms, a phenyl group, or a benzyl group, X in the formula (74) and the formula (84) represents an alkylene having 1 to 4 carbon atoms, or —O—, and n represents an integer of from 0 to 2.

5. A curable resin composition according to claim 1, wherein the component (A) has an aromatic oxycarboxylic acid unit (a′), one of an aromatic polyvalent carboxylic acid unit and an aromatic polyhydric hydroxy compound unit (b′), and one of an aromatic monohydroxy compound unit and an aromatic monocarboxylic acid unit (c′), which form the aromatic polyester, and with respect to a total of the units, a mole fraction of an aromatic compound residue having two or more rings in each of the units is 0.25 or more: 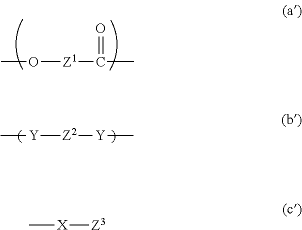
where Z¹ and Z² each independently represent a divalent aromatic group, Z³ represents a monovalent aromatic group, and X and Y each represent an ether group or a ketone group.

6. A curable resin composition according to claim 1, wherein the component (D) comprises an epoxy resin having an area percentage of aromatic carbon atoms in a resonance line area of all carbon atoms detected in ¹³C-NMR of from 30% to 95%.

7. A curable resin composition according to claim 1, wherein a content of the component (D) is from 0.1 mol to 1.5 mol with respect to 1 mol of an ester bond in the aromatic polyester.

8. A curable resin composition according to claim 1, further comprising a curing accelerator as a component (E).

9. A curable resin composition according to claim 1, further comprising a high-molecular-weight resin having a weight-average molecular weight (Mw) of 10,000 or more as a component (F).

10. A curable resin composition according to claim 9, wherein the component (F) comprises one or more kinds of high-molecular-weight resins selected from the group consisting of a polysulfone resin, a polyether sulfone resin, a polyphenylene ether resin, a phenoxy resin, a polycycloolefin resin, a hydrogenated styrene-butadiene copolymer, a hydrogenated styrene-isoprene copolymer, a polyimide resin, a polyamide imide resin, a polyether imide resin, a polycarbonate resin, a polyether ether ketone resin, and a polyester resin except the component (A).

11. A curable resin composition according to claim 1, further comprising an inorganic filler as a component (G).

12. A curable resin composition according to claim 1, further comprising a flame retardant as a component (H).

13. A varnish for a circuit board material, comprising the curable resin composition of claim 1 dissolved in a solvent.

14. A cured article, which is obtained by curing the curable resin composition of claim 1.

15. A curable composite material, comprising:
the curable resin composition of claim 1; and
a base material.

16. A composite material cured article, which is obtained by curing the curable composite material of claim 15.

17. A laminated body, comprising:
a layer of the composite material cured article of claim 16; and
a metal foil layer.

18. An electrical and electronic part, comprising the cured article of claim 16.

19. A circuit board, comprising the cured article of claim 16.

20. An aromatic polyester, comprising:
the following repeating structural units (a′) and (b′); and
the following end structural unit (c′),
wherein:
a mole fraction of the structural unit (a′) is from 15% to 94%, a mole fraction of the structural unit (b′) is from 1% to 35%, and a mole fraction of the structural unit (c′) is from 5% to 60%;
the aromatic polyester has a sum of a hydroxy group equivalent and a carboxyl group equivalent of 1,000 (g/eq) or more; and
the aromatic polyester has a catalyst-derived impurity amount of 1.0 wt % or less: 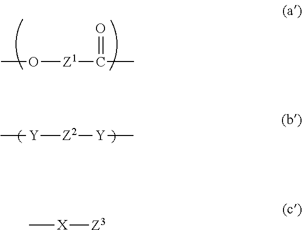
where Z¹ and Z² each independently represent a divalent aromatic group, Z³ represents a monovalent aromatic group, and X and Y each represent an ether group or a ketone group.

21. An aromatic polyester according to claim 20, wherein the Z¹ represents at least one kind of group selected from the following group (1), the Z² represents at least one kind of group selected from the following group (2), and the Z³ represents at least one kind of group selected from the following group (3): 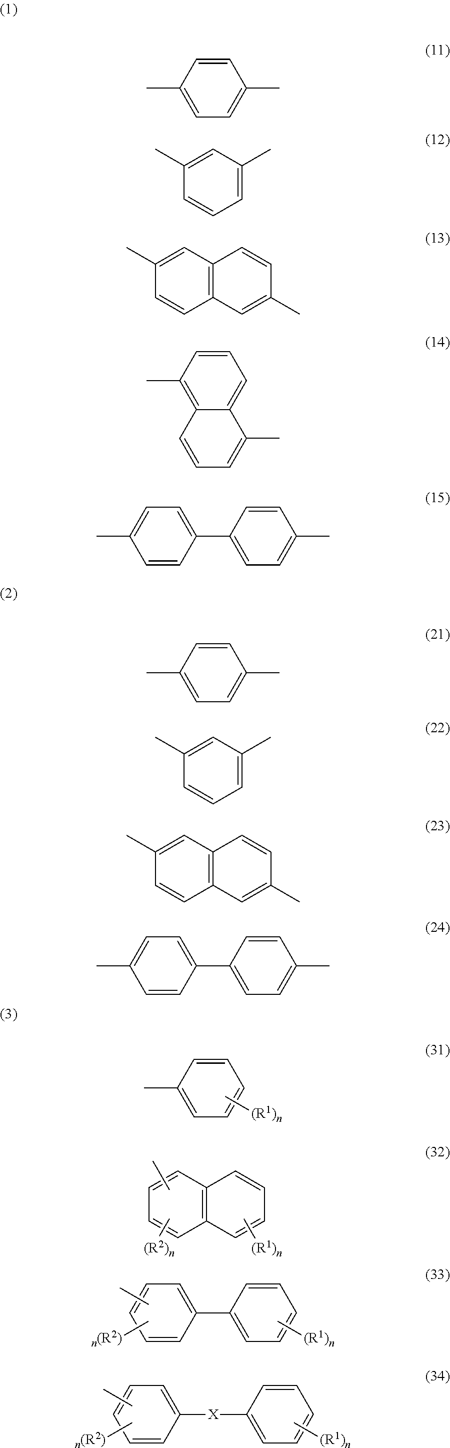
where R¹ and R² each independently represent an alkyl group having 1 to 10 carbon atoms, an alkoxy group having 1 to 10 carbon atoms, a phenyl group, or a benzyl group, X in the formula (34) represents an alkylene having 1 to 4 carbon atoms, or —O—, and n represents an integer of from 0 to 2.

22. An aromatic polyester according to claim 20, wherein the repeating structural unit (b′) comprises one of an aromatic polyvalent carboxylic acid residue and an aromatic polyhydric hydroxy compound residue, and the end structural unit (c′) comprises one of an aromatic monohydroxy compound residue and an aromatic monocarboxylic acid residue.

23. A production method for the aromatic polyester of claim 20, comprising:
blending an aromatic oxycarboxylic acid (a), one of an aromatic polyvalent carboxylic acid and an aromatic polyhydric hydroxy compound (b), and one of an aromatic monohydroxy compound and an aromatic monocarboxylic acid (c) so that a mole fraction of the aromatic oxycarboxylic acid (a) is from 15% to 94%, a mole fraction of the one of an aromatic polyvalent carboxylic acid and an aromatic polyhydric hydroxy compound (b) is from 1% to 35%, and a mole fraction of the one of an aromatic monohydroxy compound and an aromatic monocarboxylic acid (c) is from 5% to 60%; and
condensing the component (a), the component (b), and the component (c) in presence of an esterification catalyst.

24. A production method for the aromatic polyester according to claim 23, wherein the aromatic oxycarboxylic acid (a) comprises at least one kind of compound selected from the group (4), the one of an aromatic polyvalent carboxylic acid and an aromatic polyhydric hydroxy compound (b) comprises at least one kind of compound selected from one of the group (5) and the group (6), and the one of an aromatic monohydroxy compound and an aromatic monocarboxylic acid (c) comprises at least one kind of compound selected from one of the group (7) and the group (8).

25. A curable aromatic polyester, comprising:
the following repeating structural units (a′) and (b′) as main components; and
the following end structural unit (c′),
wherein:
a mole fraction of the repeating structural unit (a′) is from 15% to 95%, a mole fraction of the repeating structural unit (b′) is from 1% to 35%, and a mole fraction of the end structural unit (c′) is from 5% to 60%;
the curable aromatic polyester has a sum of a hydroxy group equivalent and a carboxyl group equivalent of 1,000 (g/eq) or more; and
the curable aromatic polyester has an impurity amount of 1.0 wt % or less: 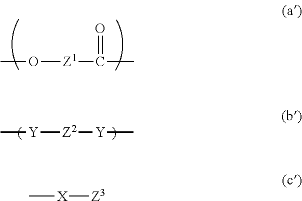
where Z¹ and Z² each independently represent a divalent aromatic group, Z³ represents a monovalent aromatic group, and X and Y each represent an ether group or a ketone group.
